(19) United States
(12) Patent Application Publication
(10) Pub. No.: US 2023/0402522 A1
(43) Pub. Date: Dec. 14, 2023

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Li-Zhen YU, New Taipei City (TW); Lin-Yu HUANG, Hsinchu (TW); Huan-Chieh SU, Tianzhong Township (TW)

(73) Assignee: Taiwan Semiconductor Manufacturing Company, Ltd., Hsinchu (TW)

(21) Appl. No.: 17/839,127

(22) Filed: Jun. 13, 2022

(51) Int. Cl. H01L 29/423; H01L 29/06; H01L 23/48; H01L 29/786; H01L 21/8234; H01L 21/768

(52) U.S. Cl. CPC H01L 29/42392; H01L 29/0665; H01L 23/481; H01L 29/78618; H01L 29/78696; H01L 21/823431; H01L 21/823412; H01L 21/823418; H01L 21/76831

(57) ABSTRACT

A method for forming a semiconductor device structure includes forming a gate structure surrounding the nanostructures. The method also includes forming source/drain structures over opposite sides of the gate structure. The method also includes forming a trench beside the source/drain structures. The method also includes depositing a first liner layer in the trench. The method also includes depositing a dummy material layer over the first liner layer. The method also includes etching the dummy material layer. The method also includes depositing a second liner layer over the dummy material layer. The method also includes forming a power via structure in the trench. The method also includes removing the dummy material layer to form an opening between the first liner layer and the second liner layer. The method also includes forming a sealing layer over the opening. An air spacer is formed under the sealing layer.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, integration of fabrication of the GAA features around the nanowire can be challenging. While the current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1ZD are perspective representations of various stages of forming a semiconductor device structure, in accordance with some embodiments of the disclosure.

FIGS. 1L-1, 1M-1, 1N-1, 1O-1, 1P-1, 1Q-1, 1R-1, 1S-1, 1T-1, 1U-1, 1V-1, 1W-1, 1X-1, 1Y-1, 1Z-1, 1ZA-1, 1ZB-1, 1ZC-1, 1ZD-1 are cross-sectional representations of various stages of forming a semiconductor device structure, in accordance with some embodiments of the disclosure.

FIG. 1Z-2 is an enlarged cross-sectional representation of a semiconductor device structure, in accordance with some embodiments of the disclosure.

FIGS. 2A-2B are perspective representations of various stages of forming a semiconductor device structure, in accordance with some embodiments of the disclosure.

FIGS. 2A-1 and 2B-1 are cross-sectional representations of various stages of forming a semiconductor device structure, in accordance with some embodiments of the disclosure.

FIG. 2A-2 is an enlarged cross-sectional representation of a semiconductor device structure, in accordance with some embodiments of the disclosure.

FIGS. 3A-3B are perspective representations of various stages of forming a semiconductor device structure, in accordance with some embodiments of the disclosure.

FIGS. 3A-1 and 3B-1 are cross-sectional representations of various stages of forming a semiconductor device structure, in accordance with some embodiments of the disclosure.

FIGS. 4A-4N are perspective representations of various stages of forming a semiconductor device structure, in accordance with some embodiments of the disclosure.

FIGS. 5A-5I are perspective representations of various stages of forming a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments for forming a semiconductor device structure are provided. The method for forming the semiconductor device structure may include forming an air spacer at the sidewall of the power via structure. The metal routing flexibility may be improved by the power via structure, and the parasitic capacitance may be reduced by the air spacer.

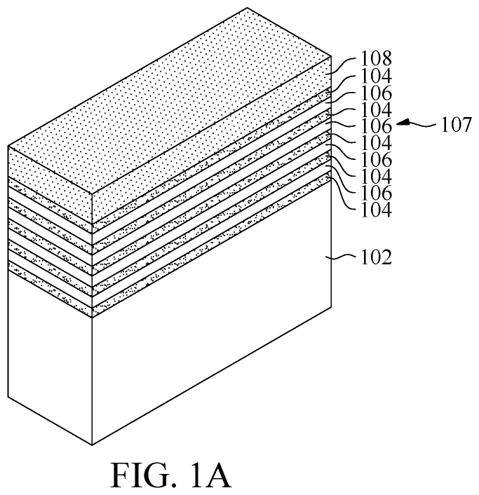

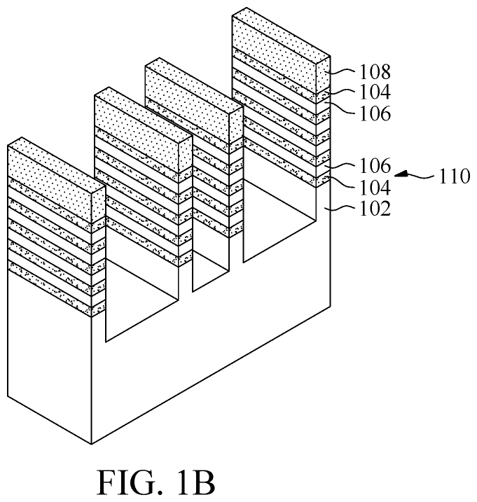

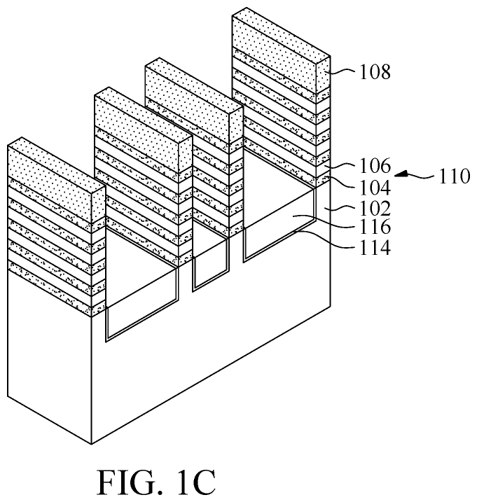

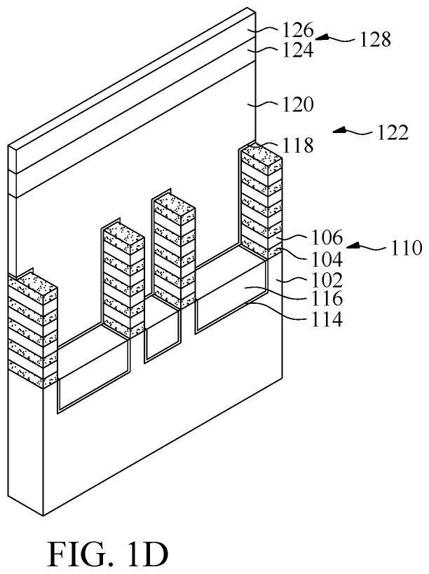

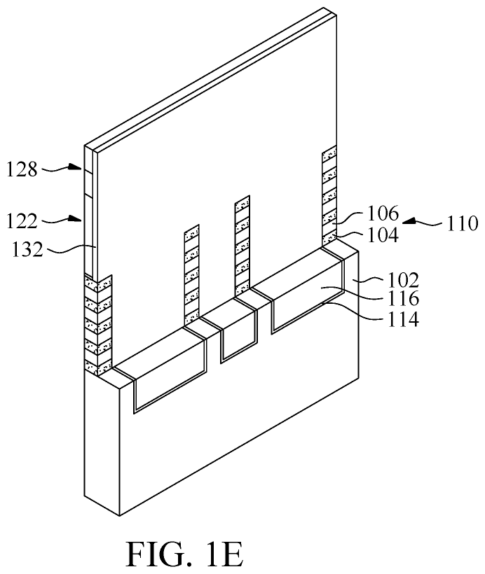

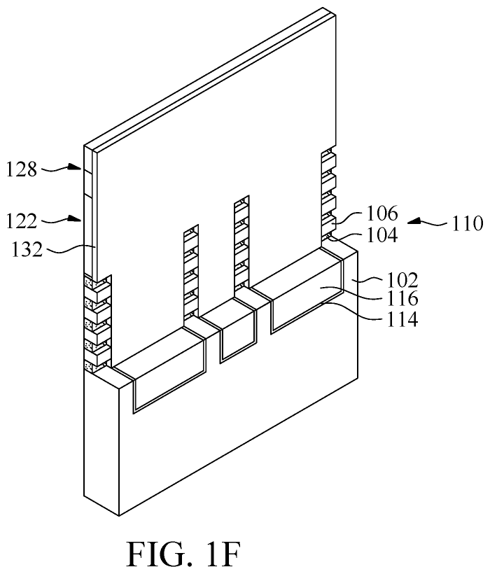

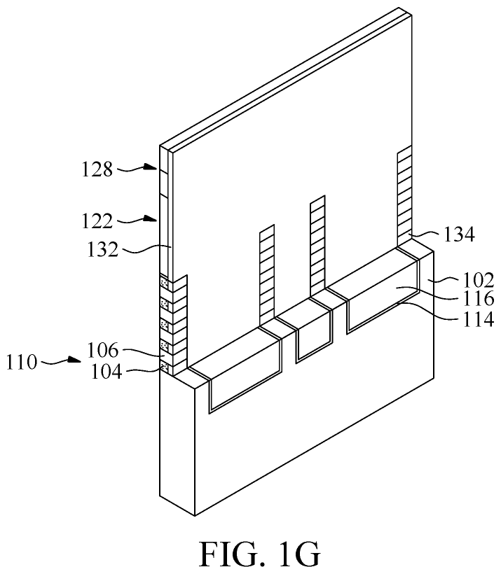

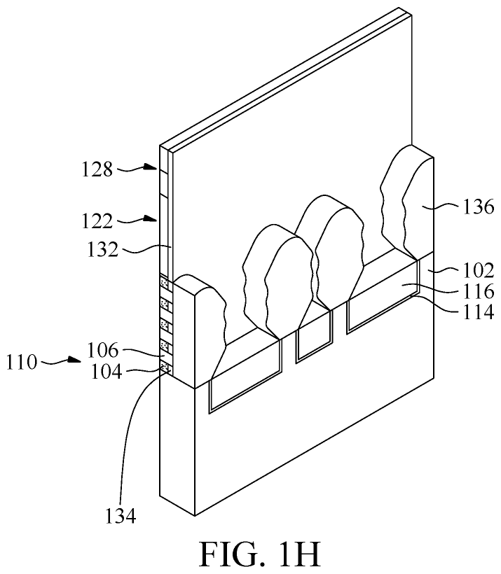

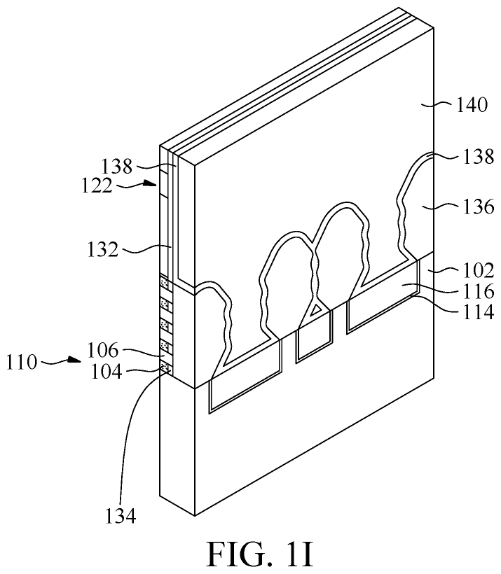

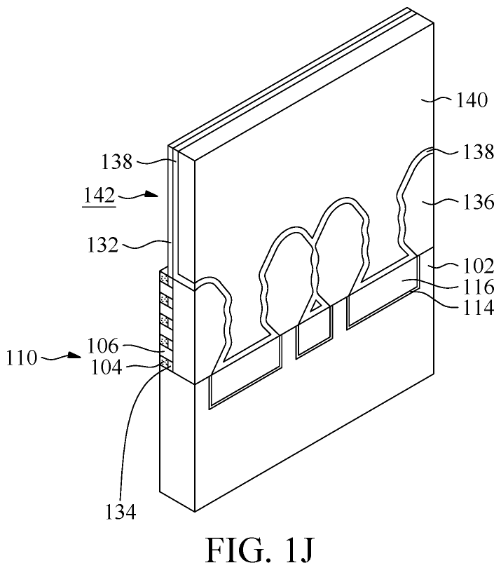

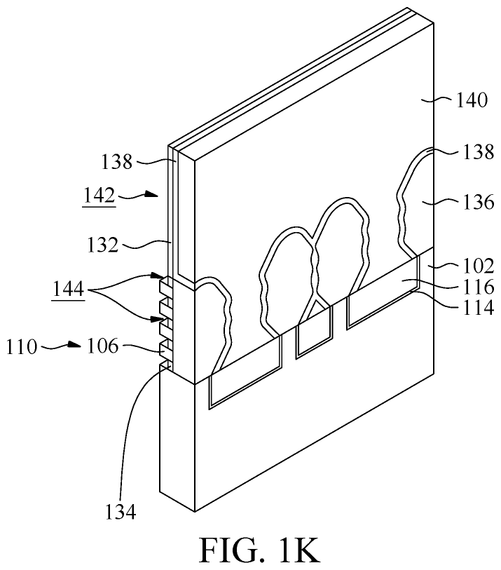

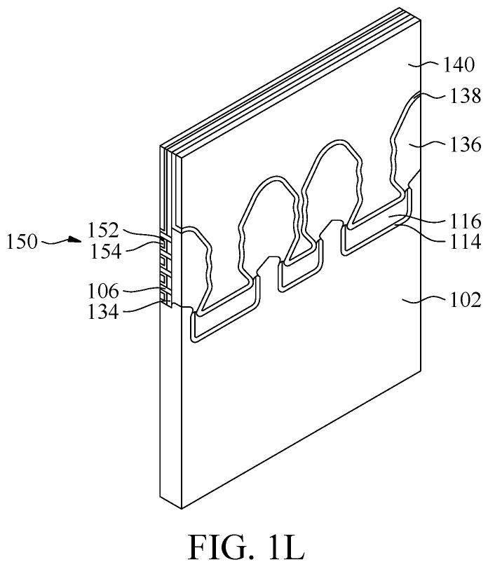

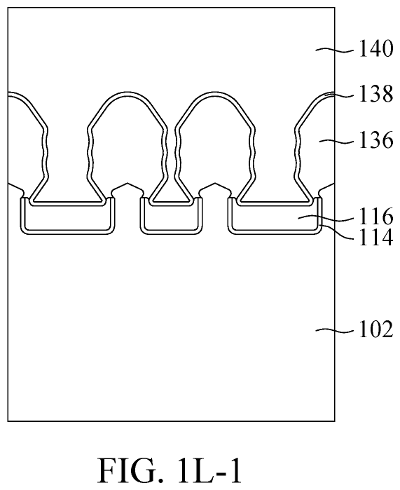

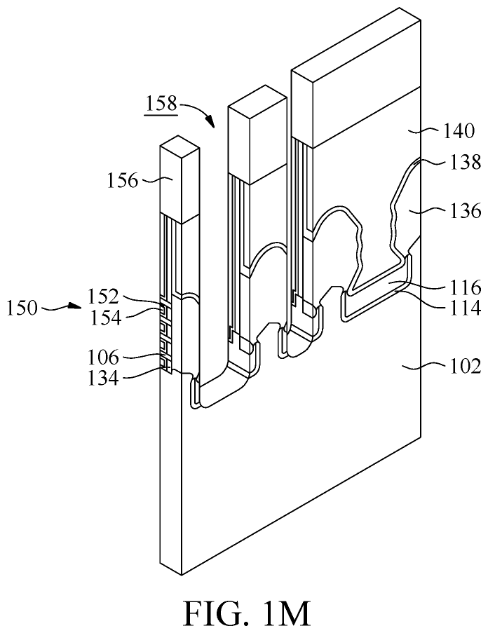

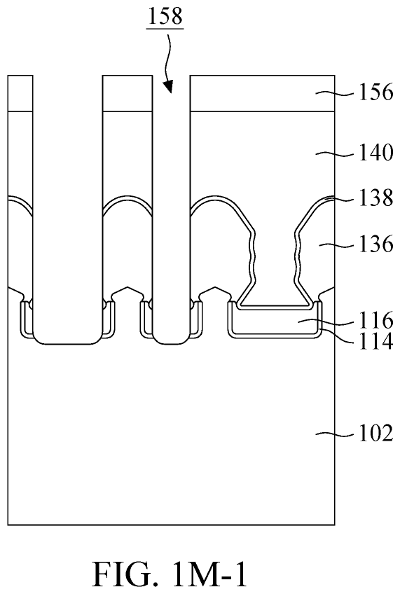

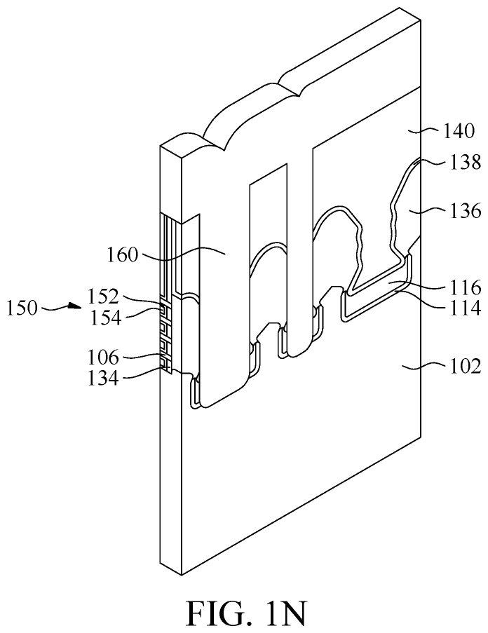

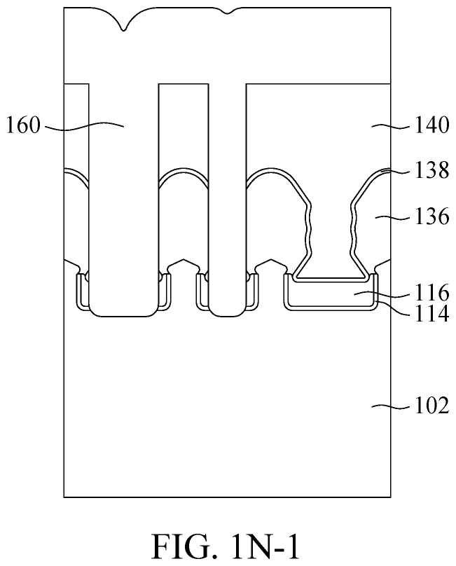

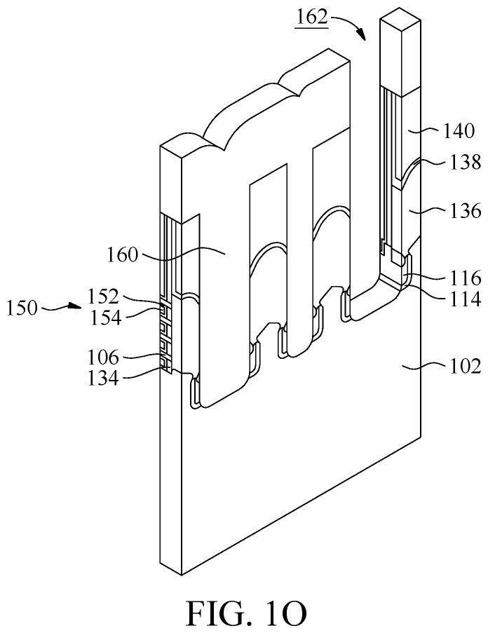

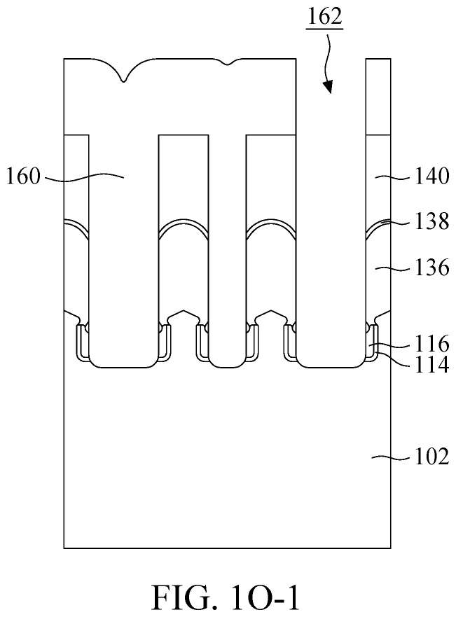

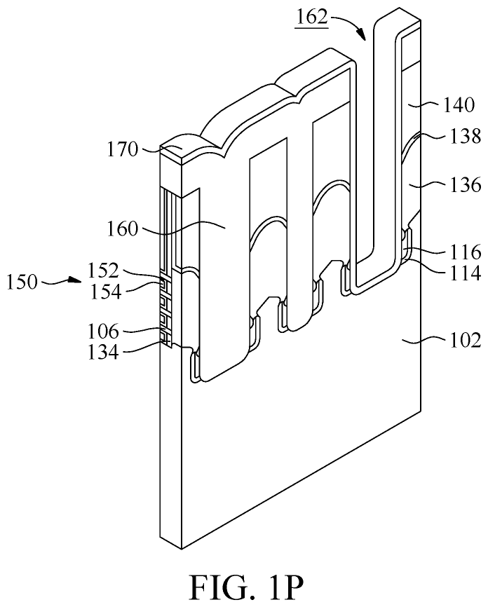

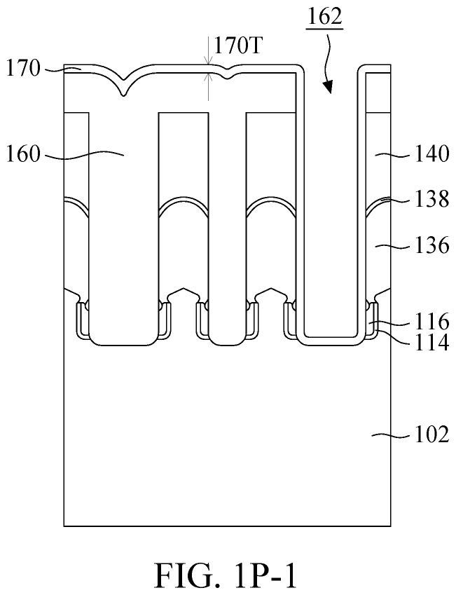

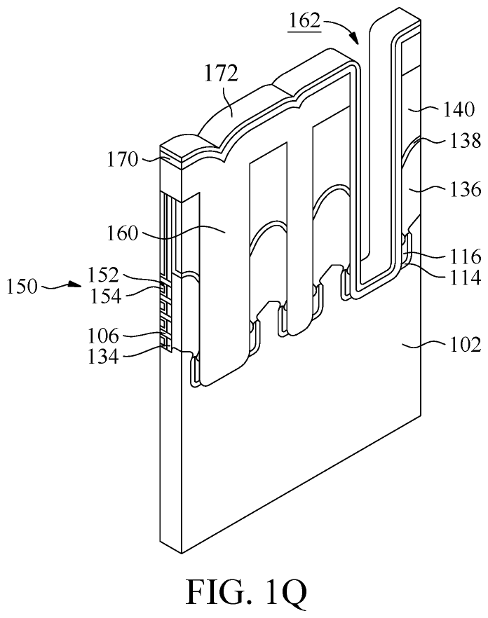

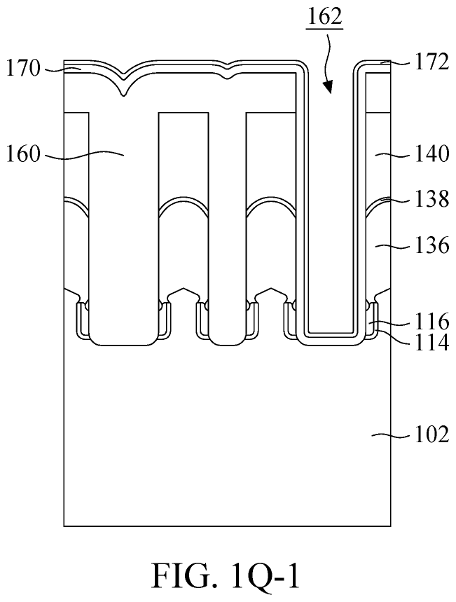

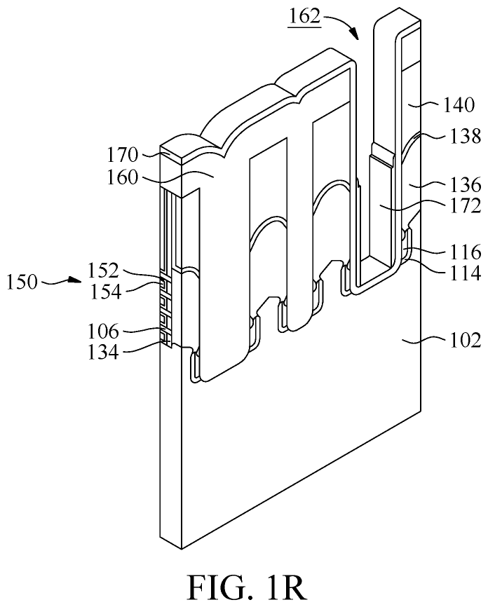

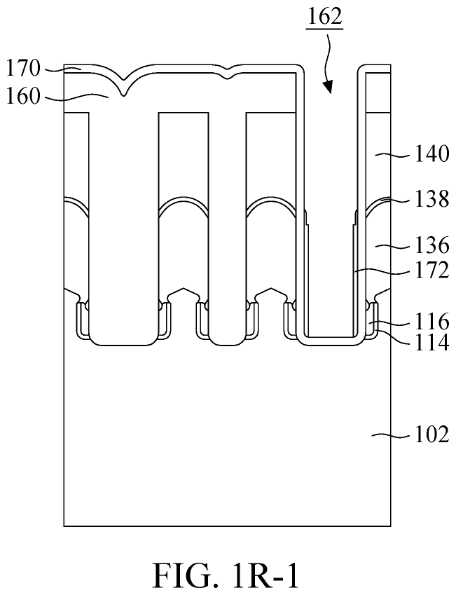

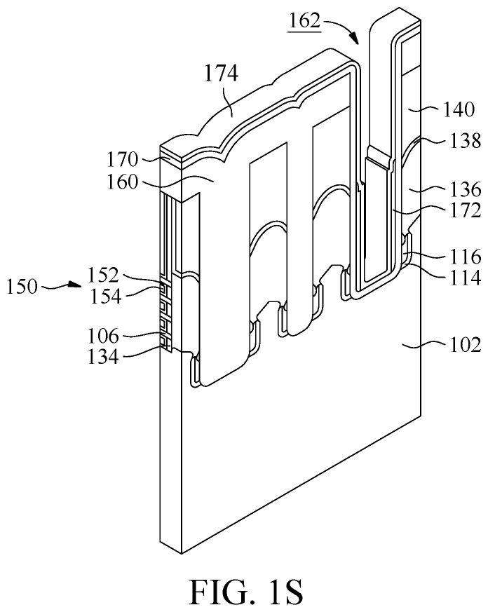

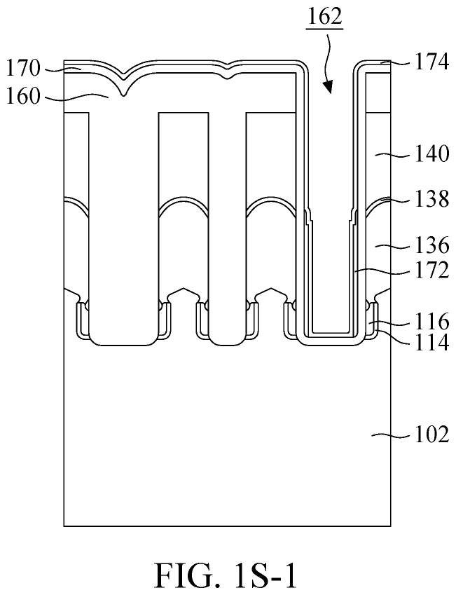

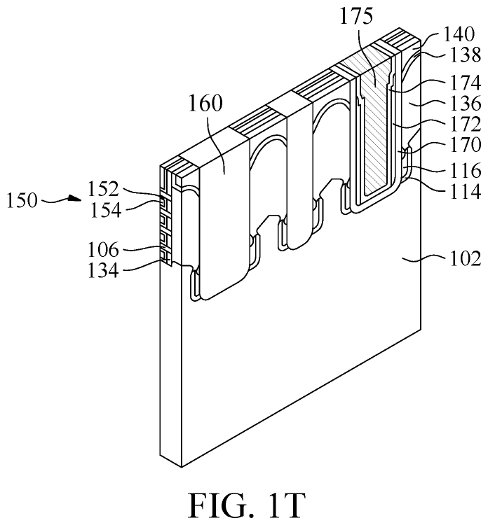

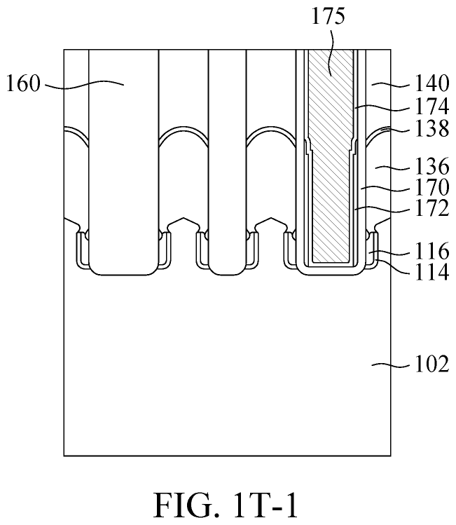

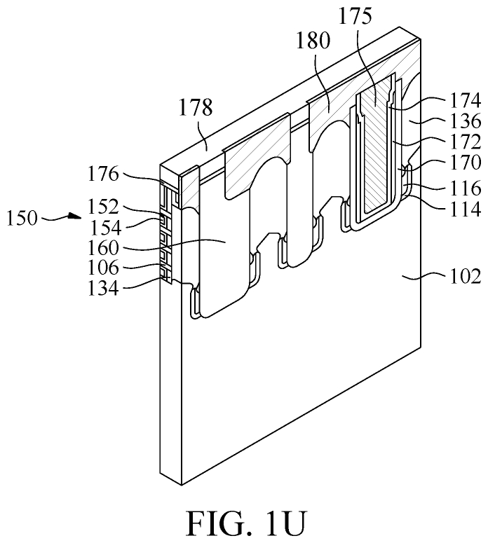

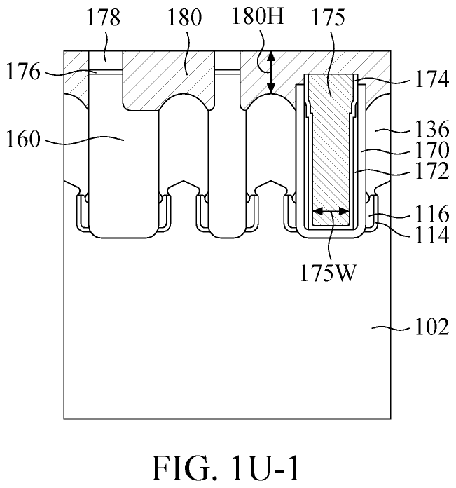

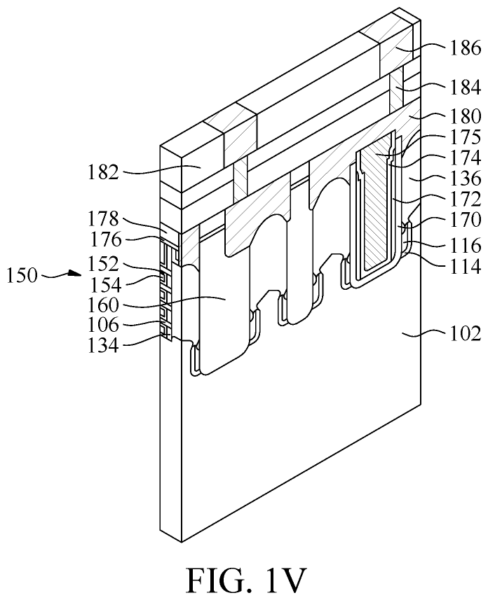

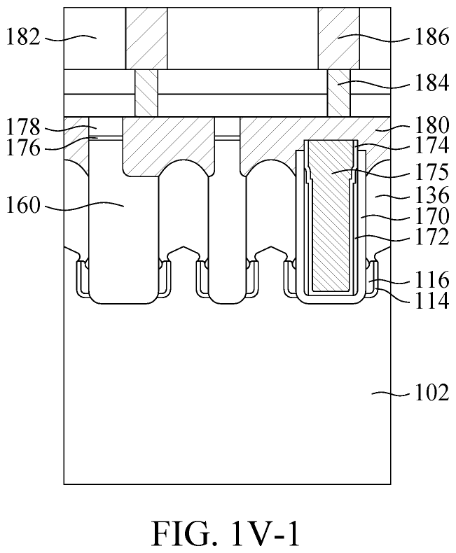

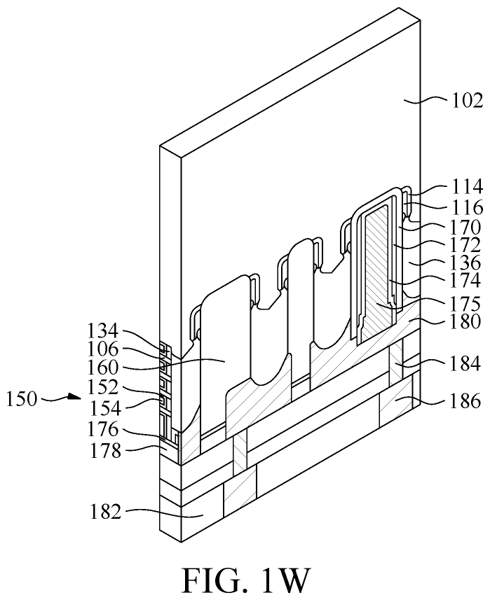

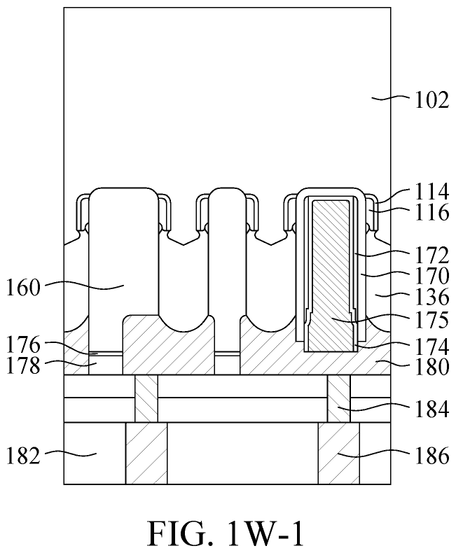

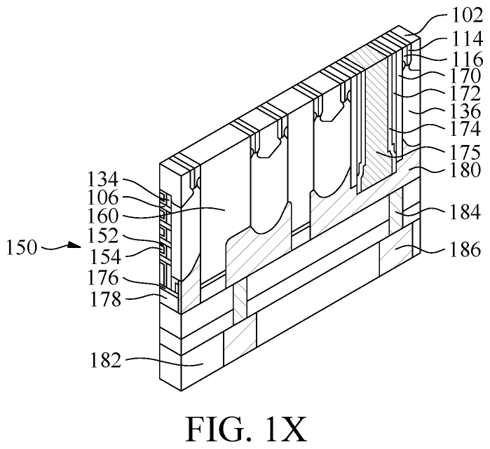

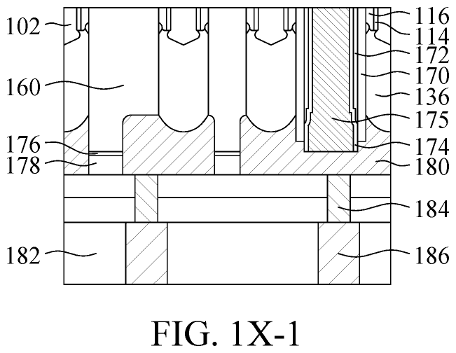

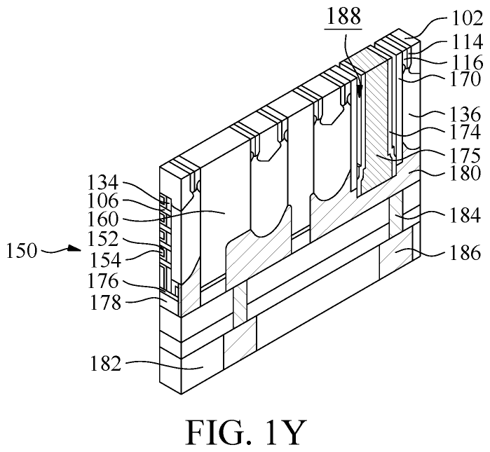

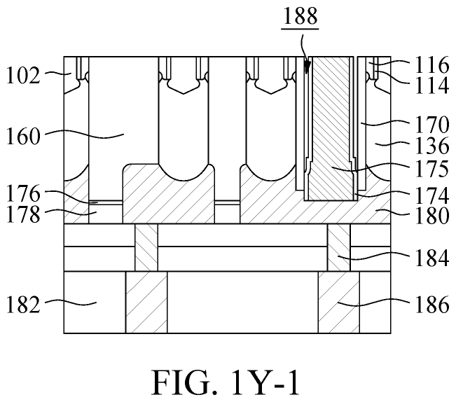

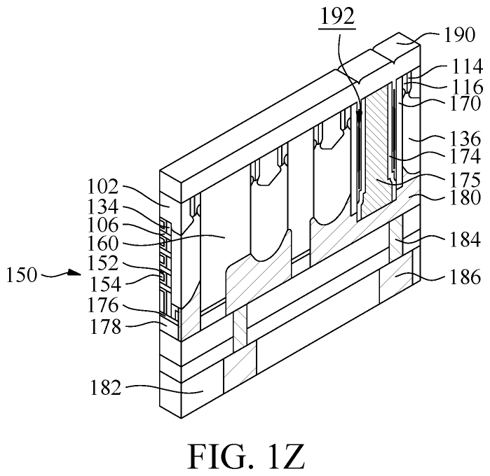

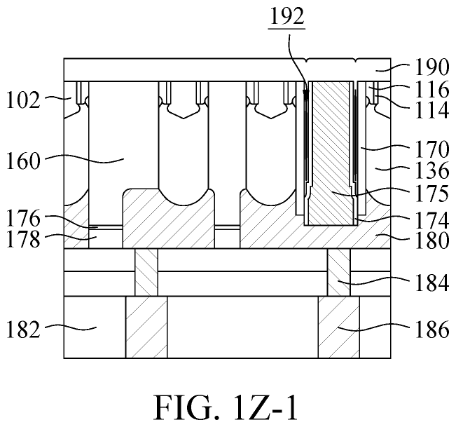

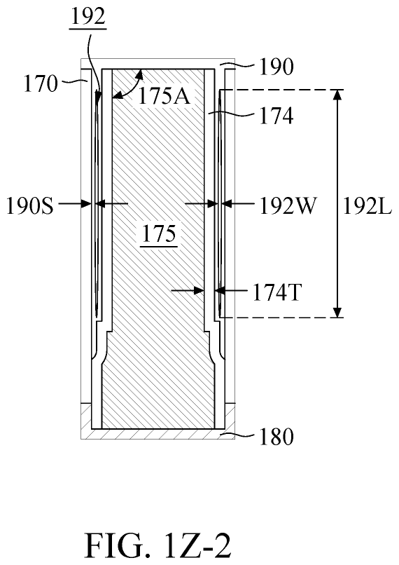

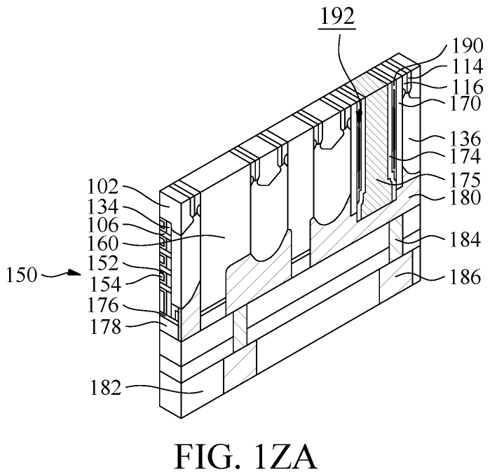

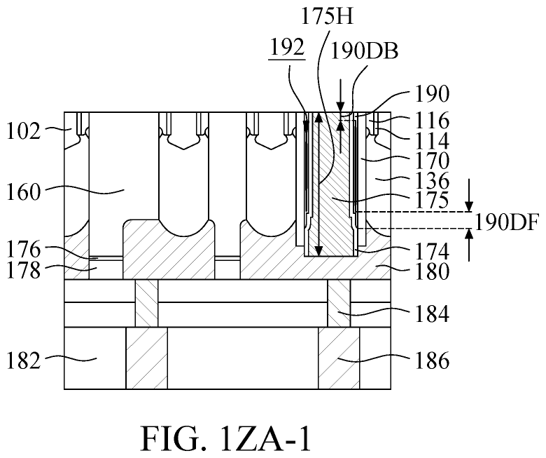

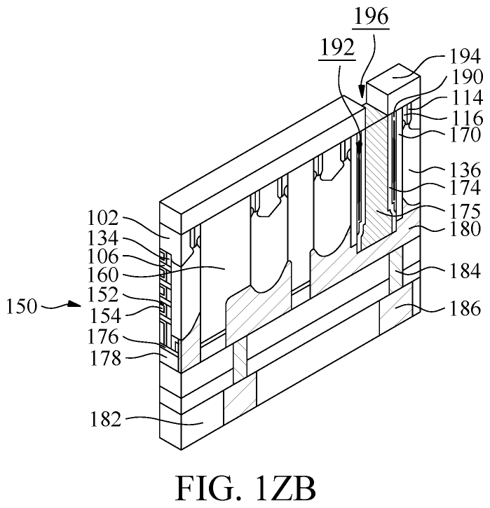

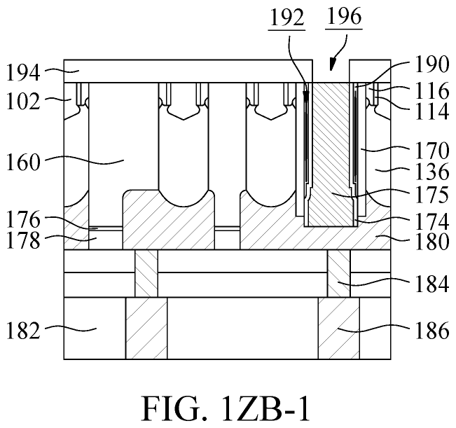

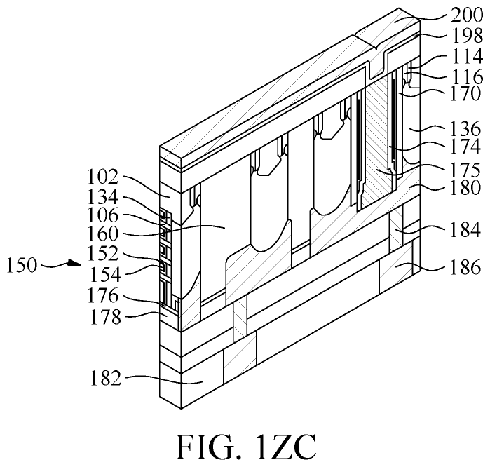

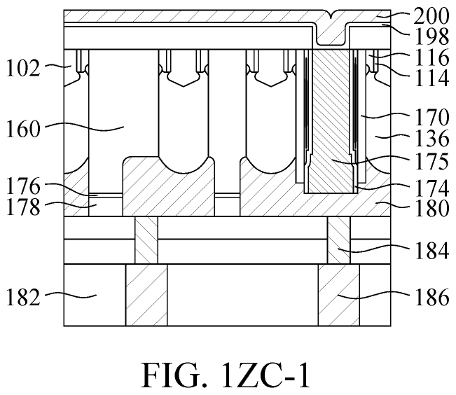

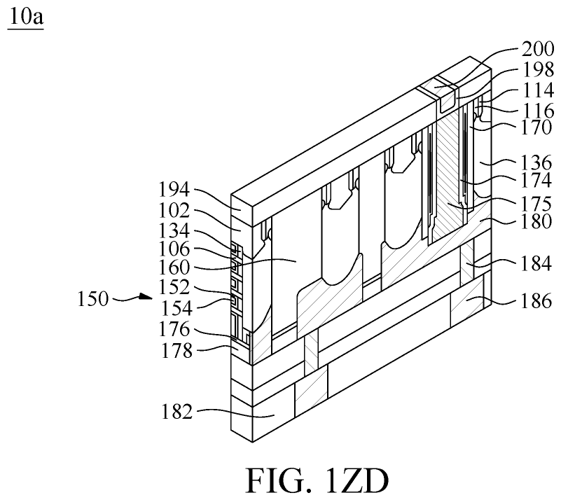

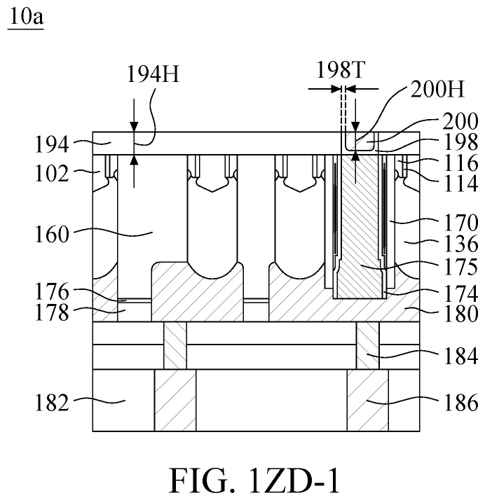

FIGS. 1A-1ZD are perspective representations of various stages of forming a semiconductor device structure 10a, in accordance with some embodiments of the disclosure. The semiconductor device structure 10a may be a gate all around (GAA) transistor structure. FIGS. 1L-1, 1M-1, 1N-1, 1O-1, 1P-1, 1Q-1, 1R-1, 1S-1, 1T-1, 1U-1, 1V-1, 1W-1, 1X-1, 1Y-1, 1Z-1, 1ZA-1, 1ZA-1, 1ZC-1, 1ZD-1 are cross-sectional representations of various stages of forming a semiconductor device structure 10a, in accordance with some embodiments of the disclosure.

A semiconductor stack including first semiconductor material layers 104 and second semiconductor material layers 106 are formed over a substrate 102, as shown in FIG. 1A in accordance with some embodiments. The substrate 102 may be a semiconductor wafer such as a silicon wafer. The substrate 102 may also include other elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium nitride, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, first semiconductor material layers 104 and second semiconductor material layers 106 are alternating stacked over the substrate 102 to form the semiconductor stack, as shown in FIG. 1A in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, for example, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are five layers of the first semiconductor material layers 104 and four layers of the second semiconductor material layers 106 shown in FIG. 1A, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure 108 is formed over the first semiconductor layers 104, as shown in FIG. 1A in accordance with some embodiments. The first mask structure 108 is made of silicon nitride, silicon carbon nitride (SiCN), or applicable material. In some embodiments, the first hard mask layers 108 are formed by a deposition process, such as low-pressure CVD (LPCVD) process, plasma enhanced CVD (PECVD) process, or another deposition process.

After the first semiconductor material layers 104 and the second semiconductor material layers 106 are formed as the semiconductor material stack over the substrate 102, the semiconductor material stack is patterned to form fin structures 110 using the mask structure 108 as a mask layer, as shown in FIG. 1B in accordance with some embodiments. The fin structures 110 may include base fin structures and the semiconductor material stacks, including the first semiconductor material layers 104 and the second semiconductor material layers 106, formed over the base fin structure.

The patterning process may including forming a mask structure 108 over the first semiconductor material layers 104 and the second semiconductor material layers 106 and etching the semiconductor material stack and the underlying substrate 102 through the mask structure 108, as shown in FIG. 1B in accordance with some embodiments. The mask structure 108 may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

The patterning process of forming the fin structures 110 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 110 are formed, a liner layer 114 is formed over the fin structures 110 and in the trenches between the fin structures 110, as shown in FIG. 1C in accordance with some embodiments. The liner layer 114 may be conformally formed over the substrate 102, the fin structure 110, and the mask structure 108 covering the fin structure 110. The liner layer 114 may be used to protect the fin structure 110 from being damaged in the following processes (such as an anneal process or an etching process). The liner layer 114 may be made of silicon nitride. The liner layer 114 may be formed by using a thermal oxidation, a CVD process, an atomic layer deposition (ALD) process, a LPCVD process, a plasma enhanced CVD (PECVD) process, a HDPCVD process, a flowable CVD (FCVD) process, another applicable process, or a combination thereof.

Next, an isolation structure material 116 is then filled into the trenches between the fin structures 110 and over the liner layer 114, as shown in FIG. 1C in accordance with some embodiments. The isolation structure material 116 may be made of silicon oxide, silicon nitride, silicon oxynitride (SiON), fluoride-doped silicate glass (FSG), other low-k dielectric materials, or a combination thereof. The isolation structure material 116 may be deposited by a deposition process, such as a chemical vapor deposition (CVD) process (e.g. a flowable CVD (FCVD) process), a spin-on-glass process, or another applicable process.

Next, the isolation structure material 116 and the liner layer 114 are etched back using an etching process, and an isolation structure 116 is formed surrounding the base fin structure, as shown in FIG. 1C in accordance with some embodiments. The etching process may be used to remove the top portion of the liner layer 114 and the top portion of the isolation structure material 116. As a result, the first semiconductor material layers 104 and the second semiconductor material layers 106 may be exposed. The isolation structure 116 may be a shallow trench isolation (STI) structure. The isolation structure 116 may be configured to electrically isolate active regions such as fin structures 110 of the semiconductor structure 10a and prevent electrical interference and crosstalk.

Next, a dummy gate structure 122 is formed over and across the fin structures 110, as shown in FIG. 1D in accordance with some embodiments. The dummy gate structure 122 may be used to define the source/drain regions and the channel regions of the resulting semiconductor structure 10a. The dummy gate structure 122 may include a dummy gate dielectric layer 118 and a dummy gate electrode layer 120. The dummy gate dielectric layer 118 and the dummy gate electrode layer 120 may be replaced by the following steps to form a real gate structure with a high-k dielectric layer and a metal gate electrode layer.

The dummy gate dielectric layer 118 may include one or more dielectric materials, such as silicon oxide, silicon nitride, silicon oxynitride (SiON), HfO₂, HfZrO, HfSiO, HfTiO, HfAlO, or a combination thereof. The dummy gate dielectric layer 118 may be formed by an oxidation process (e.g., a dry oxidation process, or a wet oxidation process), a chemical vapor deposition process, other applicable processes, or a combination thereof. Alternatively, the dummy gate dielectric layer 118 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 120 may include polycrystalline-silicon (poly-Si), poly-crystalline silicon-germanium (poly-SiGe), other applicable materials, or a combination thereof. The dummy gate electrode layer 120 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Hard mask layers 128 are formed over the dummy gate structure 122, as shown in FIG. 1D in accordance with some embodiments. The hard mask layers 128 may include multiple layers, such as an oxide layer 124 and a nitride layer 126. In some embodiments, the oxide layer 124 includes silicon oxide, and the nitride layer 126 includes silicon nitride.

The formation of the dummy gate structure 122 may include conformally forming a dielectric material as the dummy gate dielectric layer 118. Afterwards, a conductive material may be formed over the dielectric material as the dummy gate electrode layers 120, and the bi-layered hard mask layers 128, including the oxide layer 124 and the nitride layer 126, may be formed over the conductive material. Next, the dielectric material and the conductive material may be patterned and etched through the bi-layered hard mask layers 128 to form the dummy gate structure 122, as shown in FIG. 1D in accordance with some embodiments. The dummy gate dielectric layer 118 and the dummy gate electrode layer 120 may be etched by a dry etching process. After the etching process, the first semiconductor material layers 104 and the second semiconductor material layers 106 may be exposed on opposite sides of the dummy gate structure 122.

Next, a conformal dielectric layer is formed over the substrate 102 and the dummy gate structure 122, and then an etching process is performed. A pair of spacer layers 132 is formed over opposite sidewalls of the dummy gate structure 122, and a source/drain opening is formed beside the dummy gate structure 122, as shown in FIG. 1E in accordance with some embodiments.

The spacer layers 132 may be multi-layer structures formed by different materials with different etching selectivity. The spacer layers 132 may be made of silicon oxide, silicon nitride, silicon oxynitride, and/or dielectric materials. The spacer layers 132 may be formed by a chemical vapor deposition (CVD) process, a spin-on-glass process, or another applicable process.

After the spacer layers 132 are formed, the first semiconductor material layers 104 and the second semiconductor material layers 106 of the fin structure 110 not covered by the dummy gate structure 122 and the spacer layers 132 are etched to form the trenches beside the dummy gate structure 122, as shown in FIG. 1E in accordance with some embodiments.

The fin structures 110 may be recessed by performing a number of etching processes. That is, the first semiconductor material layers 104 and the second semiconductor material layers 106 of the fin structures 110 may be etched in different etching processes. The etching process may be a dry etching process or a wet etching process. The fin structures 110 may be etched by a dry etching process.

Next, the first semiconductor material layers 104 are laterally etched from the source/drain opening to form recesses, as shown in FIG. 1F in accordance with some embodiments. The outer portions of the first semiconductor material layers 104 may be removed, and the inner portions of the first semiconductor material layers 104 under the dummy gate structure 122 and the spacer layers 132 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are Ge or SiGe and the second semiconductor material layers 106 are Si, and the first semiconductor material layers 104 are selectively etched to form the recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, an inner spacer 134 is formed in the recess, as shown in FIG. 1G in accordance with some embodiments. The inner spacer 134 may provide a barrier between subsequently formed source/drain epitaxial structures and gate structure. The inner spacer 134 may be made of dielectric material such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. The inner spacer 134 may be formed using a deposition process. The deposition process may include a CVD process (such as LPCVD, PECVD, SACVD, or FCVD), an ALD process, another applicable method, or a combination thereof.

Next, a source/drain epitaxial structure 136 is formed in the source/drain opening, as shown in FIG. 1H in accordance with some embodiments. The source/drain epitaxial structure 136 may be formed over opposite sides of the dummy gate structure 122. Source/drain epitaxial structure 136 may refer to a source or a drain, individually or collectively dependent upon the context.

A strained material may be grown in the source/drain opening using an epitaxial (epi) process to form the source/drain epitaxial structure 136. In addition, the lattice constant of the strained material may be different from the lattice constant of the substrate 102. The source/drain epitaxial structure 136 may include SiGeB, SiP, SiAs, SiGe, other applicable materials, or a combination thereof. The source/drain epitaxial structure 136 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HYPE), liquid phase epitaxy (LPE), chloride vapor phase epitaxy (Cl-VPE), or any other suitable method.

The source/drain epitaxial structure 136 may be in-situ doped during the epitaxial growth process. For example, the source/drain epitaxial structures 136 may be the epitaxially grown SiGe doped with boron (B). For example, the source/drain epitaxial structure 136 may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. The source/drain epitaxial structure 136 may be doped in one or more implantation processes after the epitaxial growth process.

Next, a contact etch stop layer 138 is formed over the source/drain epitaxial structure 136, as shown in FIG. 1I in accordance with some embodiments. More specifically, the contact etch stop layer 138 covers the sidewalls of the spacer layers 132 and the source/drain epitaxial structures 136 in accordance with some embodiments.

The contact etch stop layer 138 may be made of a dielectric material such as silicon nitride, silicon oxide, silicon oxynitride (SiON), other applicable materials, or a combination thereof. The contact etch stop layer 138 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

After the contact etch stop layer 138 is formed, an inter-layer dielectric (ILD) structure 140 is formed over the contact etch stop layer 138, as shown in FIG. 1I in accordance with some embodiments. The ILD structure 140 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 140 may be formed by chemical vapor deposition (CVD), physical vapor deposition (PVD), atomic layer deposition (ALD), spin-on coating, or another applicable process.

Afterwards, a planarizing process or an etch-back process is performed on the ILD structure 140 until the top surface of the dummy gate structure 122 is exposed, as shown in FIG. 1I in accordance with some embodiments. After the planarizing process, the top surface of the dummy gate structure 122 may be substantially level with the top surfaces of the spacer layers 132 and the ILD structure 140. The planarizing process may include a grinding process, a chemical mechanical polishing (CMP) process, an etching process, other applicable processes, or a combination thereof.

Next, the dummy gate structure 122 is removed, as shown in FIG. 1J in accordance with some embodiments. Therefore, a trench 142 is formed between the spacer layers 132 over the fin structure 110 and the first semiconductor material layers 104 are exposed from the trench 142.

The dummy gate structure 122 may be removed by a dry etching process or a wet etching process. The removal process may include one or more etching processes. For example, when the dummy gate electrode layers 120 are polysilicon, a wet etchant such as a tetramethylammonium hydroxide (TMAH) solution may be used to selectively remove the dummy gate electrode layers 120. Afterwards, the dummy gate dielectric layer 118 may be removed using a plasma dry etching, a dry chemical etching, and/or a wet etching.

Next, the first semiconductor material layers 104 are removed and gaps 144 are formed between the first semiconductor material layers 104, as shown in FIG. 1K in accordance with some embodiments. More specifically, the second semiconductor material layers 106 exposed by the gaps 144 form nanostructures 106, and the nanostructures 106 are configured to function as channel regions in the resulting semiconductor devices 10a in accordance with some embodiments.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), and/or potassium hydroxide (KOH) solutions.

Next, a gate structures 150 are formed surrounding the nanostructures 106 and over the nanostructures 106. Gate structures 150 are formed surrounding the nanostructures 106 to form gate-all-around (GAA) transistor structures, as shown in FIG. 1L in accordance with some embodiments. Therefore, the gate control ability may be enhanced.

In some embodiments as shown in FIG. 1L, the gate structures 150 are multi-layered structures. Each of the gate structures 150 may include an interfacial layer, a gate dielectric layer 152, a work function layer 154, and a gate electrode layer, as shown in FIG. 1L in accordance with some embodiments. For the purpose of brevity, only the gate dielectric layer 152 and the work function layer 154 are shown in FIG. 1L.

The interfacial layer may be formed around the nanostructures 106 and on the exposed portions of the base fin structures. The interfacial layer may be made of silicon oxide, and the interfacial layer may be formed by thermal oxidation.

The gate dielectric layer 152 is formed over the interfacial layer, so that the nanostructures 106 are surrounded (e.g. wrapped) by the gate dielectric layer 152. In addition, the gate dielectric layer 152 also covers the sidewalls of the spacer layers 132 and the inner spacers 134 in accordance with some embodiments. The gate dielectric layer 152 may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other applicable high-k dielectric materials, or a combination thereof. The gate dielectric layer 152 may be formed using CVD, ALD, other applicable methods, or a combination thereof.

The work function layer 154 may be conformally formed surrounding the nanostructures 106. The work function layer 154 may be also formed over the nanostructures 106. The work function layer 154 may be multi-layer structures.

The work function layer 154 may be made of metal materials. The metal materials of the work function layer 154 may include N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The work function layer 154 may include P-work-function metal. The P-work-function metal may include titanium nitride (TiN), tungsten nitride (WN), tantalum nitride (TaN), ruthenium (Ru) or a combination thereof. The work function layer 154 may be formed by using CVD, ALD, other applicable methods, or a combination thereof.

The gate electrode layer may be formed over the work function layer 154. The gate electrode layer may be made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

After the gate structure 150 is formed, the gate structure 150 may be patterned by a hard mask layer 156 and trenches 158 are formed through the gate structure 150 between adjacent source/drain epitaxial structures 136, as shown in FIGS. 1M and 1M-1 in accordance with some embodiments. The gate structure 150 may be cut by the trenches 158. The substrate 102 and the sidewalls of the source/drain epitaxial structures 136 may be exposed in the trenches 158. The hard mask layer 156 may be made of silicon nitride, silicon carbon nitride (SiCN), or applicable material. The hard mask layer 156 may be formed by a deposition process, such as low-pressure CVD (LPCVD) process, plasma enhanced CVD (PECVD) process, or another deposition process.

Next, the hard mask layer 156 may be removed, and the trenches 158 may be filled with an isolation material 160, as shown in FIGS. 1N and 1N-1 in accordance with some embodiments. The isolation material 160 may include SiC, LaO, AlO, AlON, ZrO, HfO, SiN, ZnO, ZrN, ZrAlO, TiO, TaO, YO, TaCN, SiOCN, SiOC, SiCN, LaO, SiO, other applicable materials, or a combination thereof. The isolation material 160 may be deposited into the trenches 158 by CVD (such as HDP-CVD, PECVD, or HARP), ALD, another suitable method, or a combination thereof.

The isolation material 160 may be conformally formed in the trenches 158. Therefore, the top surface of the isolation material 160 may have a recess over the trenches 158.

Next, the ILD structure 140 may be patterned and trenches 162 are formed through the isolation material 160 and the ILD structure 140 between adjacent source/drain epitaxial structures 136, as shown in FIGS. 1O and 1O-1 in accordance with some embodiments. The substrate 102, the ILD structure 140, and the sidewalls of the source/drain epitaxial structures 136 may be exposed in the trenches 162.

Next, a first liner layer 170 is conformally formed in the trench 162 and over the isolation material 160, as shown in FIGS. 1P and 1P-1 in accordance with some embodiments. In some embodiments, the first liner layer 170 is formed over sidewalls of the source/drain epitaxial structures 136. The first liner layer 170 may prevent the underlying substrate 102 from being consumed in the following etching process. The first liner layer 170 may be made of SiC, LaO, AlO, AlON, ZrO, HfO, SiN, ZnO, ZrN, ZrAlO, TiO, TaO, YO, TaCN, SiOCN, SiOC, SiCN, LaO, SiO, other applicable materials, or a combination thereof. In some embodiments, the first liner layer 170 is made of SiN or SiCN. The first liner layer 170 may be deposited by CVD (such as HDP-CVD, PECVD, or HARP), ALD, another suitable method, or a combination thereof.

In some embodiments, the first liner layer 170 has a thickness 170T in a range of about 1 nm to about 10 nm. If the first liner layer 170 is too thick, the area of subsequently forming power via structure may be too small, and the resistance may be increased. If the first liner layer 170 is too thin, it may be difficult to form the first liner layer 170, and the first liner layer 170 may be broken.

Next, a dummy material layer 172 is conformally formed in the trench 162 and over the first liner layer 170, as shown in FIGS. 1Q and 1Q-1 in accordance with some embodiments. The dummy material layer 172 may be made of Si, SiGe, SiB, other applicable materials, or a combination thereof. The dummy material layer 172 may be deposited by CVD (such as HDP-CVD, PECVD, or HARP), ALD, another suitable method, or a combination thereof.

Afterwards, the top portion of the dummy material layer 172 is removed in an etching process, and the dummy material layer 172 remains over the lower sidewalls of the trench 162, as shown in FIGS. 1R and 1R-1 in accordance with some embodiments. After the etching process, the first liner layer 170 over the isolation material 160 and the top surface of the substrate 102 may be exposed. The first liner layer 170 over the upper sidewalls of the trench 162 may also be exposed. After the etching process, the bottom portion of the trench 162 is narrower than the top portion of the trench 162. The etching process may include an anisotropic etching process such as a dry etching process.

Next, a second liner layer 174 is conformally formed in the trench 162 and over the first liner layer 170 and the dummy material layer 172, as shown in FIGS. 1S and 1S-1 in accordance with some embodiments. The second liner layer 174 may be a blocking layer for subsequently formed power via structure. The second liner layer 174 may be made of SiC, LaO, AlO, AlON, ZrO, HfO, SiN, ZnO, ZrN, ZrAlO, TiO, TaO, YO, TaCN, SiOCN, SiOC, SiCN, LaO, SiO, other applicable materials, or a combination thereof. In some embodiments, the second liner layer 174 is made of SiN or SiCN. The second liner layer 174 may be deposited by CVD (such as HDP-CVD, PECVD, or HARP), ALD, another suitable method, or a combination thereof.

Next, a power via structure 175 is formed in the trench 162, as shown in FIGS. 1T and 1T-1 in accordance with some embodiments. In some embodiments, the second liner layer 174 is formed over sidewalls and the bottom surface of the power via structure 175. The power via structure 175 may be made of W, Ru, Co, Cu, Mo, other applicable conductive materials, or a combination thereof. In some embodiments, the power via structure 175 is made of W or Co. The power via structure 175 may be formed by a chemical vapor deposition process (CVD), a physical vapor deposition process (PVD), (e.g., evaporation or sputter), an atomic layer deposition process (ALD), a plasma enhanced CVD (PECVD), a plasma enhanced physical vapor deposition (PEPVD), an electroplating process, another suitable process, or a combination thereof to deposit the conductive materials of the power via structure 175, and then a planarization process such as a chemical mechanical polishing (CMP) process or an etch back process is optionally performed to remove excess conductive materials. After the planarization process, the top surface of the power via structure 175 may be level with the top surfaces of the ILD structure 140.

Next, a protection layer 176 is blanketly formed over the gate structure 150, the isolation material 160, and the power via structure 175, as shown in FIGS. 1U and 1U-1 in accordance with some embodiments. The protection layer 176 may be made of SiN, SiCN, other applicable materials, or a combination thereof. The protection layer 176 may be deposited by CVD (such as HDP-CVD, PECVD, or HARP), ALD, another suitable method, or a combination thereof.

After the protection layer 176 is formed, an ILD structure 178 is formed over the protection layer 176, as shown in FIGS. 1U and 1U-1 in accordance with some embodiments. The processes and materials for forming the ILD structure 178 may be the same as, or similar to, those used to form the ILD structure 140. For the purpose of brevity, the descriptions of these processes are not repeated herein.

Next, a source/drain opening may be formed through the ILD structures 140 and 178, the protection layer 176, and the isolation material 160 to expose the source/drain epitaxial structure 136 by performing an etching process. A silicide layer may be formed over the source/drain epitaxial structure 136 before the source/drain contact structure is formed. The silicide layer may reduce the contact resistance between the source/drain epitaxial structure 136 and the subsequently formed source/drain contact structure over the source/drain epitaxial structure 136. The silicide layer may be made of titanium silicide (TiSi₂), nickel silicide (NiSi), cobalt silicide (CoSi), or other suitable low-resistance materials.

The silicide layer may be formed over the source/drain epitaxial structure 136 by forming a metal layer over the source/drain epitaxial structure 136 first. The metal layer may react with the source/drain epitaxial structure 136 in an annealing process and a silicide layer may be produced. Afterwards, the unreacted metal layer may be removed in an etching process and the silicide layer may be left.

Afterwards, a source/drain contact structure 180 is formed into the source/drain opening over the source/drain epitaxial structure 136, as shown in FIGS. 1U and 1U-1 in accordance with some embodiments. In some embodiments, the source/drain contact structure 180 is at the front side of the power via structure 175. The source/drain contact structure 180 may be made of W, Ru, Co, Cu, Mo, TaN, TiN, other applicable conductive materials, or a combination thereof. In some embodiments, the source/drain contact structure 180 has a height 180H in a range of about 20 nm to about 60 nm.

The source/drain contact structure 180 may be formed by a chemical vapor deposition process (CVD), a physical vapor deposition process (PVD), (e.g., evaporation or sputter), an atomic layer deposition process (ALD), a plasma enhanced CVD (PECVD), a plasma enhanced physical vapor deposition (PEPVD), an electroplating process, another suitable process, or a combination thereof to deposit the conductive materials of the source/drain contact structure 180, and then a planarization process such as a chemical mechanical polishing (CMP) process or an etch back process is optionally performed to remove excess conductive materials. After the planarization process, the top surface of the source/drain contact structure 180 may be level with the top surfaces of the ILD structure 178.

In some embodiments, the top surface of the power via structure 175 near the source/drain contact structure 180 is wider than the bottom surface of the power via structure 175 near a subsequently formed metal layer at the back-side of the substrate 102. In some embodiments, the power via structure 175 has a width 175W in a range of about 10 nm to about 30 nm. If the power via structure 175 is too wide, the power via structure 175 may be too close to the source/drain epitaxial structures 136 and the isolation may not be enough. If the power via structure 175 is too narrow, it may be difficult to fill the trench 162 with the power via material 174. The area of the power via structure 175 may also be too small, and the resistance may be increased.

Next, dielectric layers 182 may be formed over the ILD structure 178, and a via structure 184 and metal lines 186 are formed through the dielectric layers 182 over the source/drain contact structure 180, as shown in FIGS. 1V and 1V-1 in accordance with some embodiments. The dielectric layers 182 may be a multi-layer structure. The via structure 184 may be formed through lower dielectric layers 182 over the source/drain contact structure 180, and the metal line 186 may be formed through upper dielectric layers 182 over the via structure 184. In some embodiments, the source/drain contact structure 180 is electrically connected to the metal line 186.

Next, the substrate 102 is flipped over, and the bottom surface of the substrate 102 faces upwards, as shown in FIGS. 1W and 1W-1 in accordance with some embodiments.

Next, the substrate 102 is thinned down to expose the bottom surfaces of the power via structure 175 and the isolation material 160, as shown in FIGS. 1X and 1X-1 in accordance with some embodiments. The substrate 102 may be thinned down by a grinding process, a chemical mechanical polishing (CMP) process, an etching process, other applicable processes, or a combination thereof.

Next, the dummy material layer 172 is removed by an etching process, and a gap is formed between the first liner layer 170 and the second liner layer 174, as shown in FIGS. 1Y and 1Y-1 in accordance with some embodiments. The etching process may use chemical base such as He, H₂, HBr, or O₂. The etching process may be performed at a pressure in a range of about 0.1 Torr to about 10 Torr. The etching process may be performed at a temperature in a range of about 10° C. to about 100° C. If the etching pressure and temperature are too great, the etching rate may be too slow, and the throughput may be worse. If the etching pressure and temperature are too less, the etching selectivity between dummy material and other material may be worse.

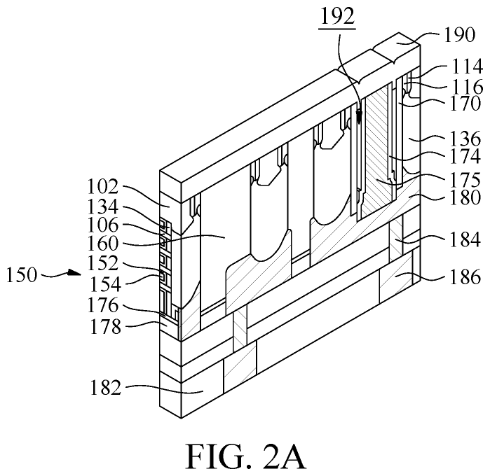

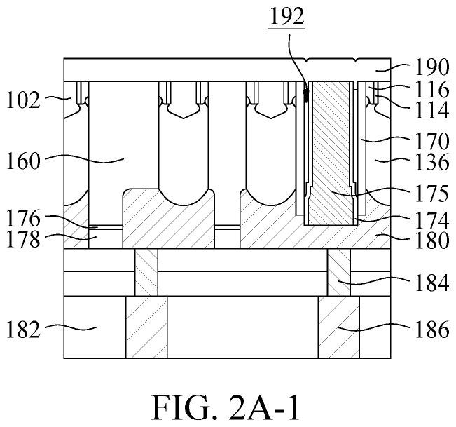

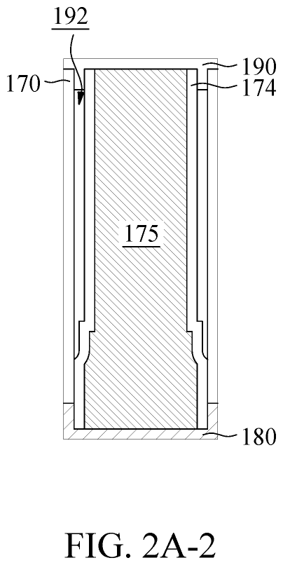

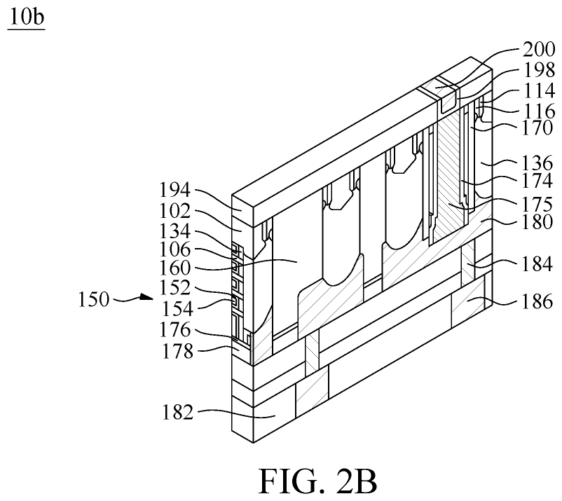

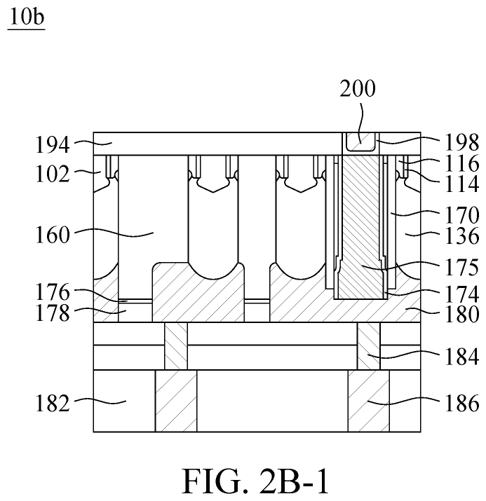

Next, a sealing layer 190 is formed over the opening 188, and an air spacer 192 is formed in between the first liner layer 170 and the second liner layer 174, as shown in FIGS. 1Z and 1Z-1 in accordance with some embodiments. FIG. 1Z-2 is an enlarged cross-sectional representation of a semiconductor device structure 10a, in accordance with some embodiments of the disclosure.

In some embodiments, the air spacer 192 is formed under the sealing layer 190. In some embodiments, the air spacer 192 is formed between the power via structure 175 and the source/drain epitaxial structure 136. The air spacer 192 may reduce the parasitic capacitance between the power via structure 175 and the gate structure 150.

The sealing layer 190 may be made of SiC, LaO, AlO, AlON, ZrO, HfO, SiN, ZnO, ZrN, ZrAlO, TiO, TaO, YO, TaCN, SiOCN, SiOC, SiCN, LaO, SiO, other applicable materials, or a combination thereof. In some embodiments, the sealing layer 190 is made of SiN or SiOC. The sealing layer 190 may be deposited by CVD (such as HDP-CVD, PECVD, or HARP), ALD, another suitable method, or a combination thereof.

In some embodiments, the sealing layer 190 covers the sidewalls of the first liner layer 170 and the second liner layer 174. In some embodiments, the first liner layer 170 is in contact with the second liner layer 174. In some embodiments, the first liner layer 170 is in direct contact with the second liner layer 174 at the end near the front side. In some embodiments, the first liner layer 170 is separated from the second liner layer 174 by the sealing layer 190 at the end near the backside. In some embodiments, the sealing layer 190 deposited between the first liner layer 170 and the second liner layer 174 near the metal layer that is subsequently formed at the back side of the substrate 102. In some embodiments, the air spacer 192 is surrounded by the sealing layer 190.

In some embodiments, the sealing layer 190 over the sidewalls of the power via structure 175 has a thickness 190S in a range of about 0.5 nm to about 3 nm. If the sealing layer 190 is too thick, the air spacer 192 may be too small, and the capacitance reduction may be not enough.

In some embodiments, the air spacer 192 has a width 192W in a range of about 1 nm to about 10 nm. If the width 192W of the air spacer 192 is too great, the area of the power via structure 175 may be too small, and the resistance may be increased. In some embodiments, the air spacer 192 has a length 192L in a range of about 30 nm to about 100 nm. If the air spacer 192 is too short, the capacitance reduction may be not enough.

In some embodiments, the second liner layer 174 has a thickness 174T in a range of about 1 nm to about 10 nm. If the second liner layer 174 is too thick, the area of the power via structure 175 may be too small, and the resistance may be increased. If the second liner layer 174 is too thin, the second liner layer 174 may not be formed, and metal material of the power via structure 175 may be exposed in the air spacer 192.

In some embodiments, the power via structure 175 has an angle 175A in a range of about 90 degree to about 100 degree. If the angle 175A of the power via structure 175 is too great, the isolation may be worse. If the angle 175A of the power via structure 175 is too less, it may be difficult to fill the power via material into the trench 162.

Next, planarization process such as CMP or an etch-back process may be performed, and the surfaces of the power via structure 175 and the isolation material 160 are exposed, as shown in FIGS. 1ZA and 1ZA-1 in accordance with some embodiments.

In some embodiments, the sealing layer 190 over the air spacer 192 at the front side has a depth 190DF, and the sealing layer 190 over the air spacer 192 at the backside has a depth 190DB. In some embodiments, the depth 190DF of the sealing layer 190 is in a range of about 1 nm to about 10 nm. In some embodiments, the depth 190DB of the sealing layer 190 is in a range of about 1 nm to about 10 nm. If the depth 190DF or 190DB of the sealing layer 190 are too great, the air spacer 192 may be too small and the capacitance reduction may be not enough. If the depth 190DF or 190DB of the sealing layer 190 are too less, the subsequently formed metal layer may be formed in the air spacer 192.

In some embodiments, the power via structure 175 has a height 175H in a range of about 50 nm to about 150 nm. If the power via structure 175 is too high, it may be difficult to fill the trench 162 with the power via structure material.

Next, a hard mask layer 194 is deposited under the power via structure 175, and an opening 196 is formed to expose the power via structure 175, as shown in FIGS. 1ZB and 1ZB-1 in accordance with some embodiments. The hard mask layer 194 may be made of SiC, LaO, AlO, AlON, ZrO, HfO, SiN, ZnO, ZrN, ZrAlO, TiO, TaO, YO, TaCN, SiOCN, SiOC, SiCN, LaO, SiO, other applicable materials, or a combination thereof. The opening 196 may be formed by a patterning process including a photolithography process and an etching process.

Next, a barrier layer 198 may be conformally formed over the hard mask layer 194 and in the opening 196, as shown in FIGS. 1ZC and 1ZC-1 in accordance with some embodiments. The barrier layer 198 may be formed before filling the opening 196 with the conductive material to prevent the conductive material from diffusing out. The barrier layer 198 may also serve as an adhesive or glue layer. The material of the barrier layer 198 may be TaN, TiN, W, Ru, Co, other applicable materials, or a combination thereof. The barrier layer 198 may be formed by depositing the barrier layer materials by a physical vapor deposition process (PVD) (e.g., evaporation or sputtering), an atomic layer deposition process (ALD), an electroplating process, other applicable processes, or a combination thereof.

Afterwards, a metal layer 200 is conformally formed over the barrier layer 198 and into the opening 196, as shown in FIGS. 1ZC and 1ZC-1 in accordance with some embodiments. In some embodiments, the metal layer 200 is formed at the back side of the power via structure 175. The metal layer 200 may be made of W, Ru, Co, Cu, Mo, TaN, TiN, other applicable conductive materials, or a combination thereof.

The metal layer 200 may be formed by a chemical vapor deposition process (CVD), a physical vapor deposition process (PVD), (e.g., evaporation or sputter), an atomic layer deposition process (ALD), a plasma enhanced CVD (PECVD), a plasma enhanced physical vapor deposition (PEPVD), an electroplating process, another suitable process, or a combination thereof to deposit the conductive materials of the metal layer 200.

Later, a planarization process such as a chemical mechanical polishing (CMP) process or an etch back process is optionally performed to remove excess conductive materials, as shown in FIGS. 1ZD and 1ZD-1 in accordance with some embodiments. After the planarization process, the surface of the hard mask layer 194 is exposed.

In some embodiments, the hard mask layer 194 has a height 194H in a range of about 3 nm to about 50 nm. In some embodiments, the barrier layer 198 has a thickness 198T in a range of about 3 nm to about 10 nm. In some embodiments, the metal layer 200 has a height 200H in a range of about 3 nm to about 50 nm.

By forming an air spacer 192 at the sidewalls of the power via structure 175 to provide power from the back side, the metal routing flexibility may be improved, and the parasitic capacitance between the gate structure 168 and the power via structure 175 may be reduced.

Many variations and/or modifications may be made to the embodiments of the disclosure. FIGS. 2A-2B are perspective representations of various stages of forming a semiconductor device structure 10b, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 2A in accordance with some embodiments, the sealing layer 190 only forms at the top portion of the opening 188.

By increasing the deposition rate of the sealing layer 190, the sealing layer 190 may only forms at the top portion of the opening 188, and the lower sidewalls of the first liner layer 170 and the second liner layer 174 are exposed in the air spacer 192, as shown in FIGS. 2A, 2A-1 and 2A-2 in accordance with some embodiments. Since the air spacer 192 is enlarged, the parasitic capacitance is further reduced.

Afterwards, the hard mask layer 194 and the metal layer 200 is formed under the power via structure 175, as shown in FIGS. 2B and 2B-1 in accordance with some embodiments. The processes and materials for forming the hard mask layer 194 and the metal layer 200 may be the same as, or similar to, those used to form the hard mask layer 194 and the metal layer 200 in the previous embodiments. For the purpose of brevity, the descriptions of these processes are not repeated herein.

By forming an air spacer 192 at the sidewalls of the power via structure 175 to provide power from the back side, the metal routing flexibility may be improved, and the parasitic capacitance between the gate structure 168 and the power via structure 175 may be reduced. The air spacer 192 may be enlarged by speeding up the sealing process, and the parasitic capacitance may be further reduced.

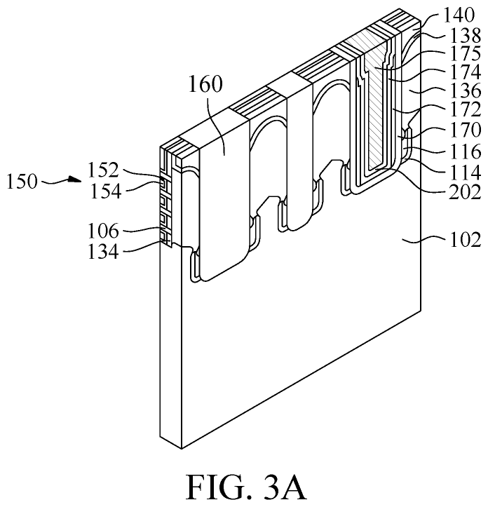

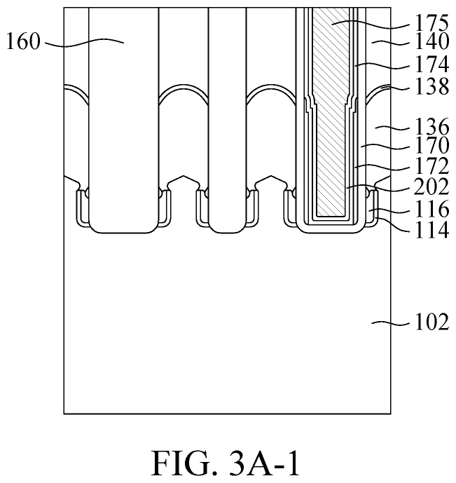

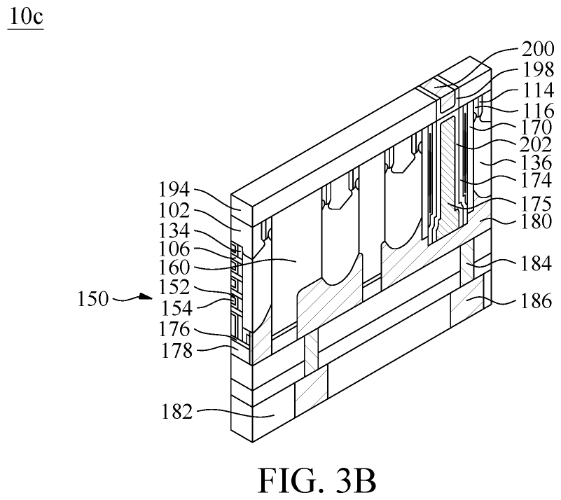

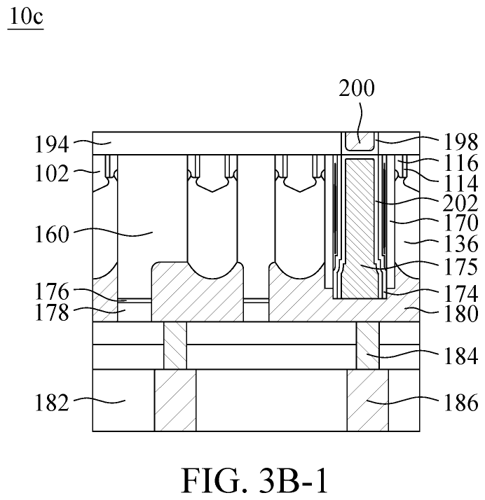

Many variations and/or modifications may be made to the embodiments of the disclosure. FIGS. 3A-3B are perspective representations of various stages of forming a semiconductor device structure 10c, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 3A in accordance with some embodiments, a glue layer 202 is formed at the sidewalls of the power via structure 175.

After depositing the second liner layer 174, the glue layer 202 is deposited in the trench 162 over the second liner layer 174, and the power via structure 175 is formed in the trench 162, as shown in FIGS. 3A and 3A-1 in accordance with some embodiments. The glue layer 202 may be made of TaN, TiN, other applicable materials, or a combination thereof. The glue layer 202 may be formed by depositing the barrier layer materials by a physical vapor deposition process (PVD) (e.g., evaporation or sputtering), an atomic layer deposition process (ALD), an electroplating process, other applicable processes, or a combination thereof.

Afterwards, the hard mask layer 194 with the metal layer 200 is formed under the power via structure 175, as shown in FIGS. 3B and 3B-1 in accordance with some embodiments. The processes and materials for forming the hard mask layer 194 and the metal layer 200 may be the same as, or similar to, those used to form the hard mask layer 194 and the metal layer 200 in the previous embodiments. For the purpose of brevity, the descriptions of these processes are not repeated herein.

By forming an air spacer 192 at the sidewalls of the power via structure 175 to provide power from the back side, the metal routing flexibility may be improved, and the parasitic capacitance between the gate structure 168 and the power via structure 175 may be reduced. The glue layer 202 may be formed at the sidewalls of the power via structure 175.

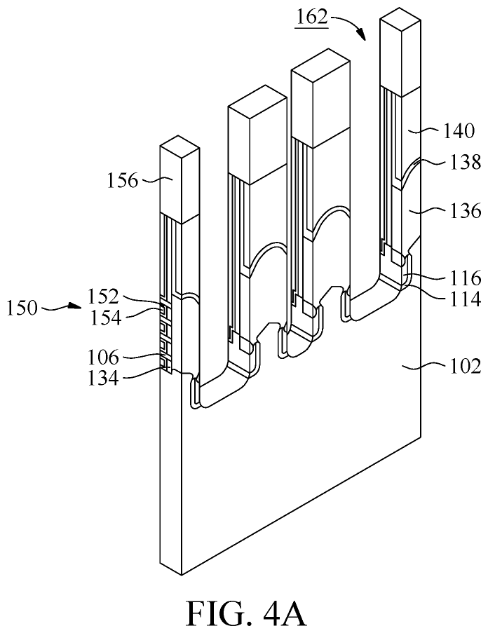

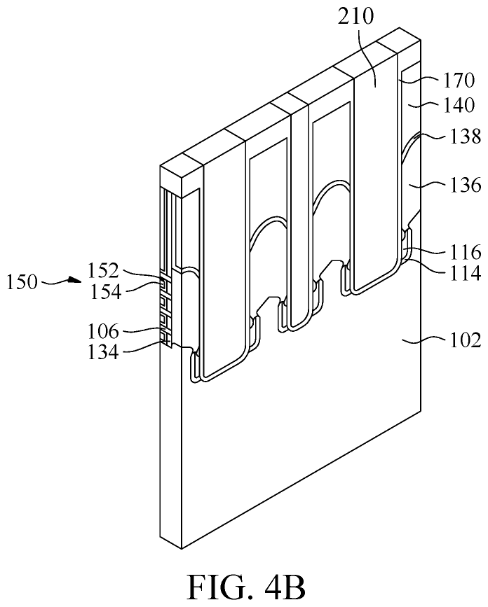

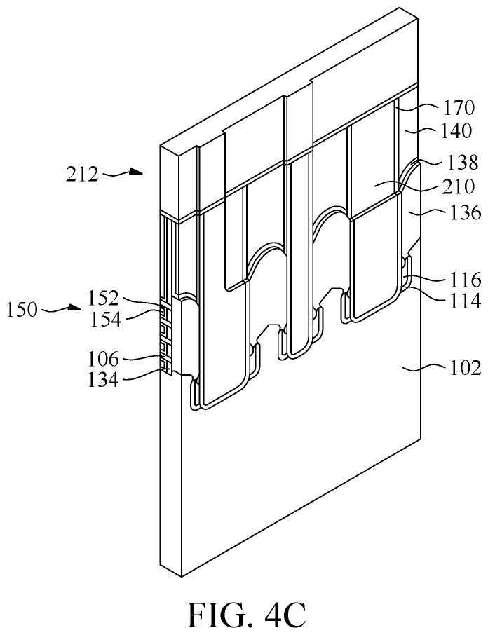

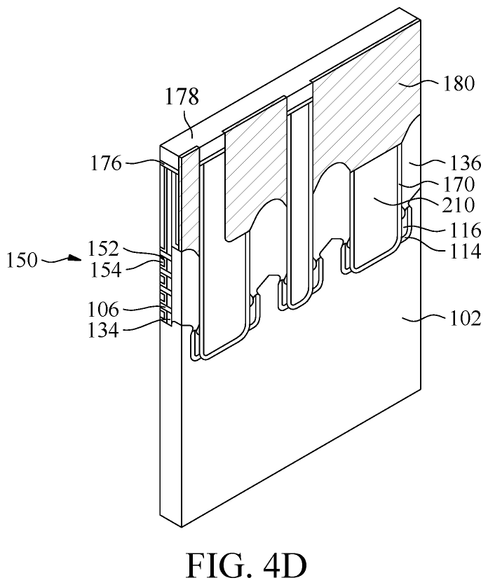

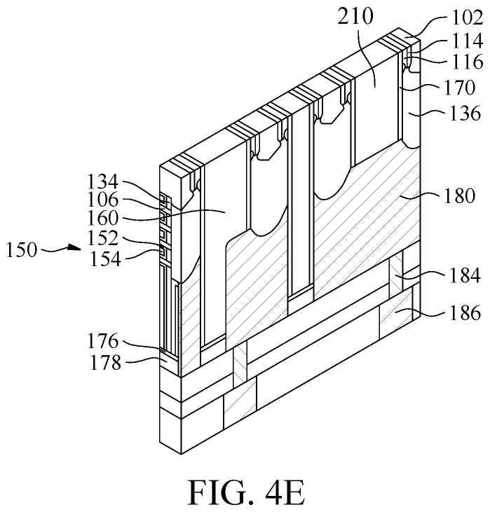

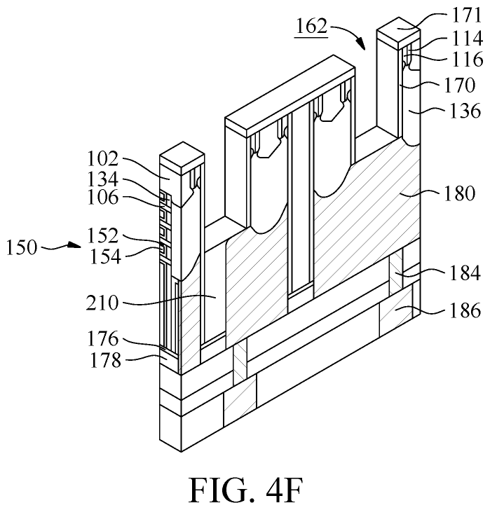

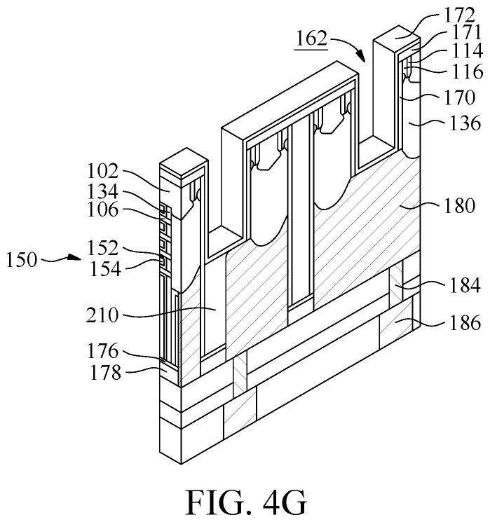

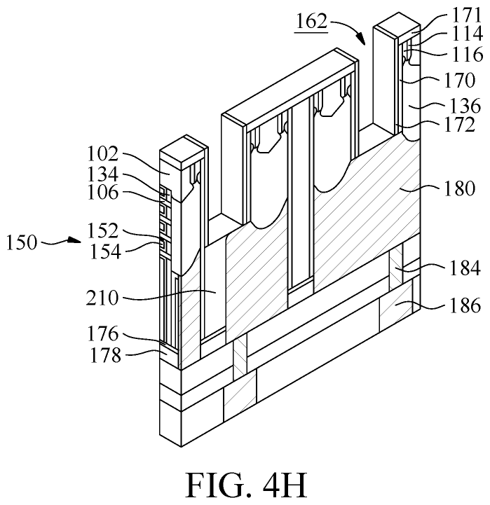

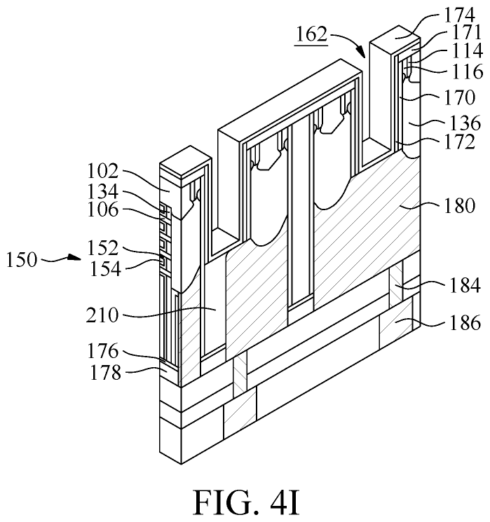

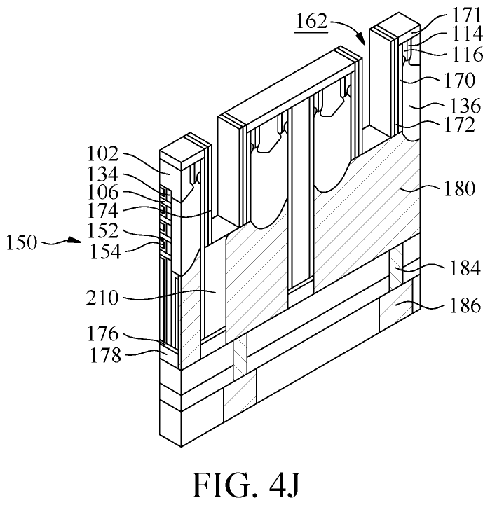

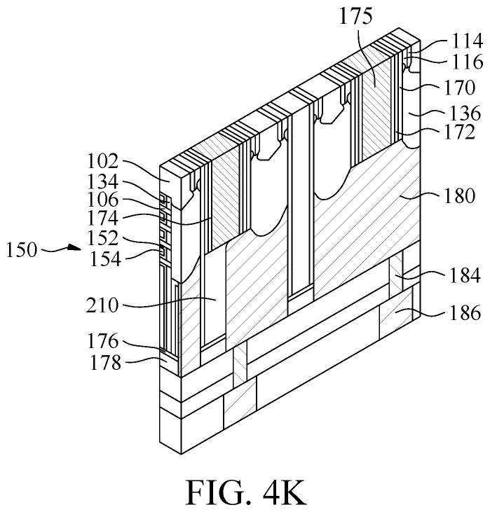

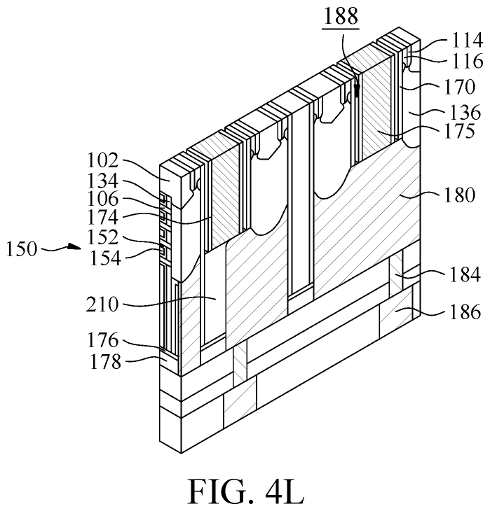

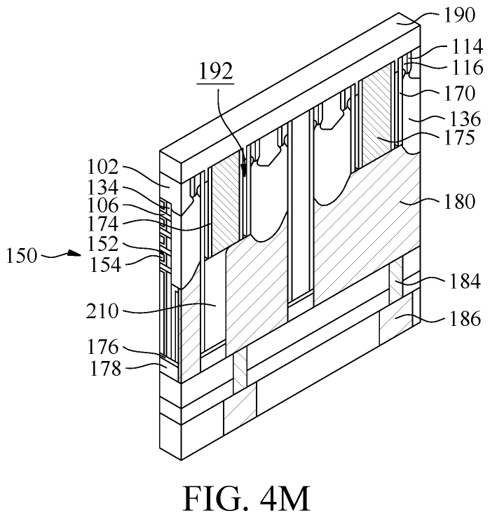

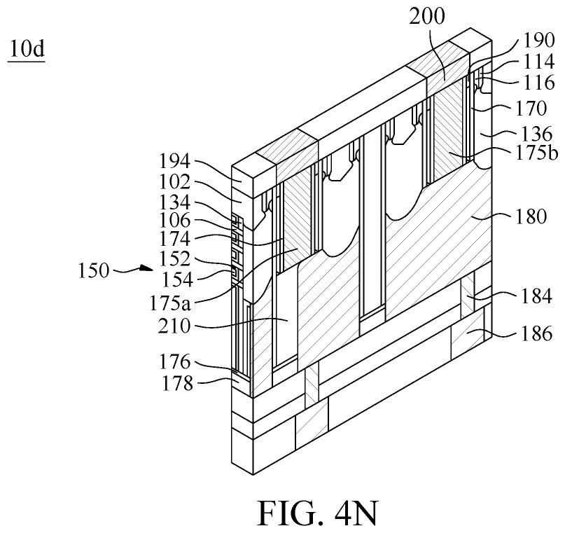

Many variations and/or modifications may be made to the embodiments of the disclosure. FIGS. 4A-4N are perspective representations of various stages of forming a semiconductor device structure 10d, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 4A-4D in accordance with some embodiments, the source/drain contact structure 180 are formed before forming the power via structure 175.

In some embodiments as shown in FIG. 4A, the trench 162 is formed by the hard mask layer 156. Later, a first liner layer 170 is formed in the trench 162, and a dielectric layer 210 is formed in the trench 162, as shown in FIG. 4B in accordance with some embodiments. The dielectric layer 210 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or other applicable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The dielectric layer 210 may be formed by chemical vapor deposition (CVD), physical vapor deposition, (PVD), atomic layer deposition (ALD), spin-on coating, or other applicable processes.

Next, the dielectric layer 210 is patterned by a mask structure 212, and source/drain contact structure 180 is formed, as shown in FIGS. 4C and 4D in accordance with some embodiments. The mask structure 212 may be a multi-layer structure. The mask structure 212 may be made of silicon oxide, silicon nitride, other applicable materials, or a combination thereof. The mask structure 212 may be formed by chemical vapor deposition (CVD), physical vapor deposition, (PVD), atomic layer deposition (ALD), spin-on coating, or other applicable processes. It should be noted that, the number of layers of the mask structure 212 shown in FIG. 4C is merely an example, and the embodiments are not limited thereto.

Later, the substrate 102 is flipped over and thinned down to expose the dielectric layer 210, as shown in FIG. 4E in accordance with some embodiments.

Next, the dielectric layer 210 is patterned by a mask layer 171, and the trench 162 is formed, the first liner layer 170 remains over sidewalls of the trench 162, as shown in FIG. 4F in accordance with some embodiments. The mask layer 171 may be made of silicon nitride, silicon oxide, other applicable materials, or a combination thereof. The mask layer 171 may be formed by chemical vapor deposition (CVD), physical vapor deposition, (PVD), atomic layer deposition (ALD), spin-on coating, or other applicable processes.

Afterwards, the dummy material layer 172 is conformally formed in the trench 162, as shown in FIG. 4G in accordance with some embodiments. Later, the dummy material layer 172 formed over the bottom surface of the trench 162 is removed, and the dummy material layer 172 remains over sidewalls of the trench 162, as shown in FIG. 4H in accordance with some embodiments.

Later, a second liner layer 174 is conformally formed in the trench 162, as shown in FIG. 4I in accordance with some embodiments. The processes and materials for forming the first liner layer 170, the dummy material layer 172, and the second liner layer 174 may be the same as, or similar to, those used to form the first liner layer 170, the dummy material layer 172, and the second liner layer 174 in the previous embodiments. For the purpose of brevity, the descriptions of these processes are not repeated herein.

Later, the second liner layer 174 formed over the bottom surface of the trench 162 is removed, and the source/drain contact structure 180 is exposed, as shown in FIG. 4J in accordance with some embodiments. The etching process may use chemical base such as NH₃, HF, CH₃F, or Cl. The etching process may be performed at a pressure in a range of about 0.1 Torr to about 10 Torr. The etching process may be performed at a temperature in a range of about 10° C. to about 100° C.

Next, the power via structure 175 is formed in the trench 162, and the power via structure 175 is in contact with the source/drain contact structure 180, as shown in FIG. 4K in accordance with some embodiments. A planarization process such as a chemical mechanical polishing (CMP) process may be performed to remove excess conductive materials and the mask layer 171. After the planarization process, the top surface of the power via structure 175 may be level with the top surfaces of the first liner layer 170.

Later, the dummy material layer 172 is removed, and the opening 188 is formed between the first liner layer 170 and the second liner layer 174, as shown in FIG. 4L in accordance with some embodiments.

Next, a sealing layer 190 is formed over the opening 188, and the air spacer 192 is formed in between the first liner layer 170 and the second liner layer 174, as shown in FIG. 4M in accordance with some embodiments.

Next, the hard mask layers 194 are formed over the power via structure 175, and the metal layer 200 is formed in the hard mask layers 194 and is in contact with the power via structure 175, as shown in FIG. 4N in accordance with some embodiments.

The processes and materials for forming the sealing layer 190, the hard mask layers 194, and the metal layer 200 may be the same as, or similar to, those used to form the sealing layer 190, the hard mask layer 194, and the metal layer 200 in the previous embodiments. For the purpose of brevity, the descriptions of these processes are not repeated herein.

In some embodiments, the source/drain contact structure 180 partially lands over the power via structure 175a. The power via structure 175 may partially overlap the source/drain contact structure 180. In some embodiments, the source/drain contact structure 180 fully lands over the power via structure 175b. In some embodiments, the source/drain contact structure 180 fully overlaps with the power via structure 175b.

By forming an air spacer 192 at the sidewalls of the power via structure 175 to provide power from the back side, the metal routing flexibility may be improved, and the parasitic capacitance between the gate structure 168 and the power via structure 175 may be reduced. The power via structure 175 may be formed after the substrate 102 has been flipped.

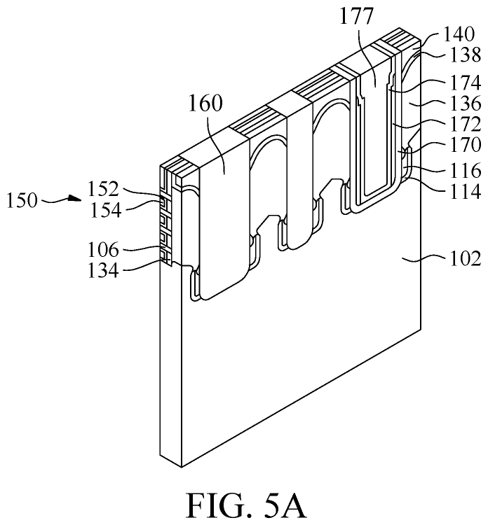

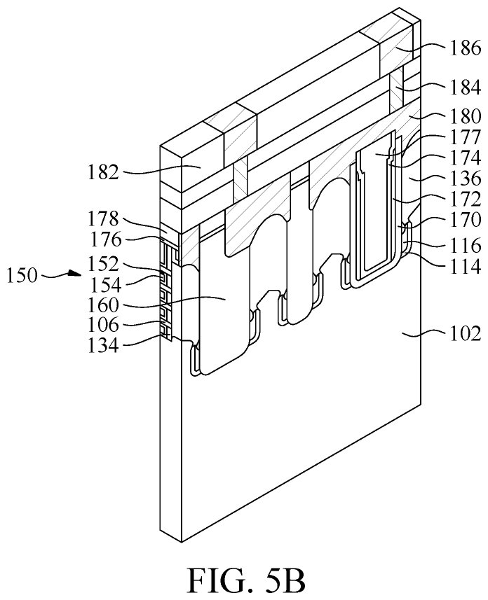

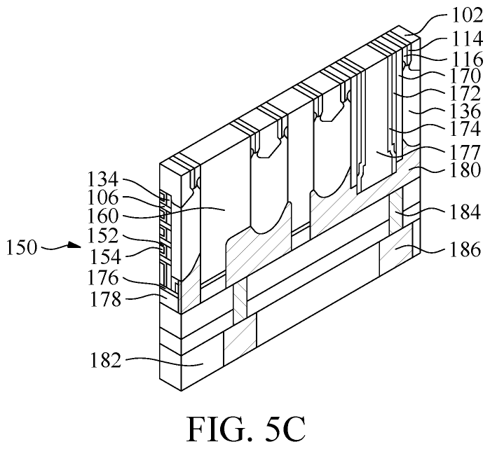

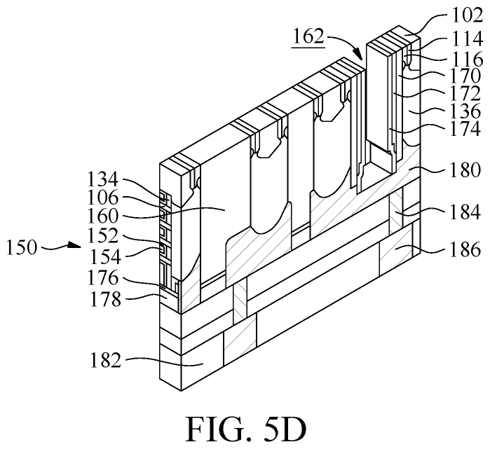

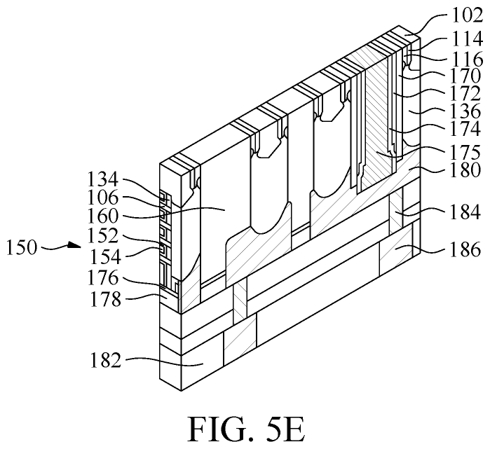

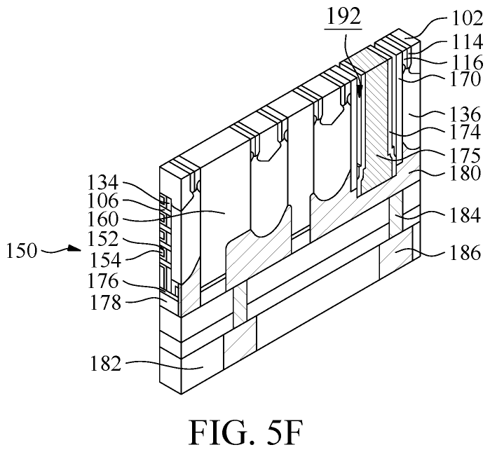

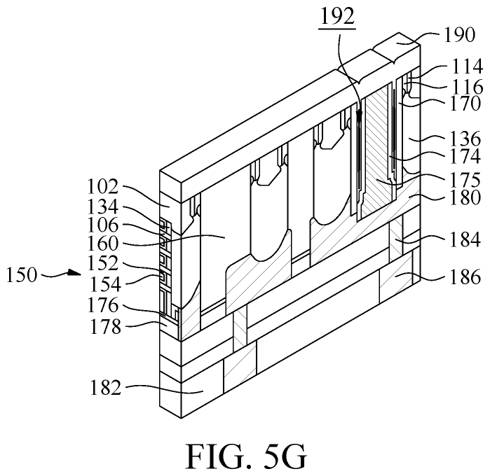

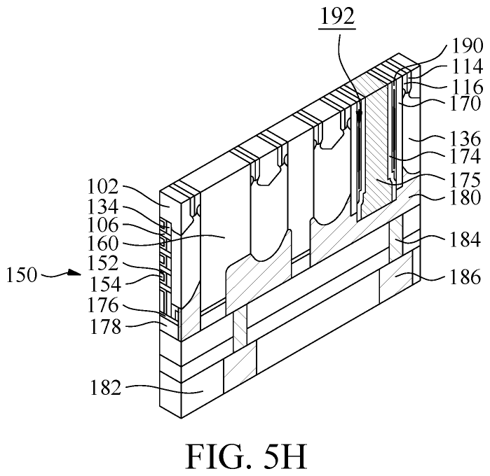

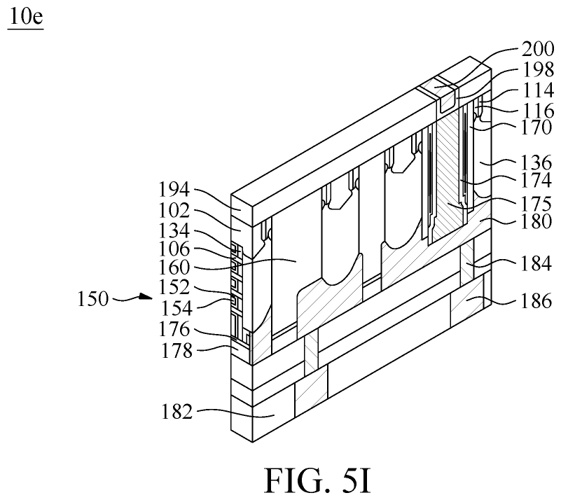

Many variations and/or modifications may be made to the embodiments of the disclosure. FIGS. 5A-5I are perspective representations of various stages of forming a semiconductor device structure 10e, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 5A-5C in accordance with some embodiments, a dummy power via structure 177 is formed in the trench 162.

The dummy power via structure 172 may be made of dielectric material such as oxides, nitrides, other applicable materials, or a combination thereof. The dummy power via structure 172 may be formed by chemical vapor deposition (CVD), physical vapor deposition, (PVD), atomic layer deposition (ALD), spin-on coating, or other applicable processes.

Afterwards, the source/drain contact structure 180, the via structure 184, and the metal lines 186 and are formed, as shown in FIG. 5B in accordance with some embodiments. Next, the substrate 102 is flipped and thinned down, and the dummy power via structure 177 is removed, as shown in FIGS. 5C and 5D in accordance with some embodiments. The power via structure 175 is then formed in the trench 162, as shown in FIG. 5E in accordance with some embodiments.

Afterwards, the dummy material layer 172 is removed, and the air spacer 192 is formed by sealing the opening 188 with the sealing layer 190, as shown in FIG. 5F-5H in accordance with some embodiments. The processes and materials for forming the power via structure 175 and the sealing layer 190 may be the same as, or similar to, those used to form the power via structure 175 and the sealing layer 190 in the previous embodiments. For the purpose of brevity, the descriptions of these processes are not repeated herein.

Afterwards, the hard mask layer 194 with a metal layer 200 is formed under the power via structure 175, as shown in FIG. 5I in accordance with some embodiments. The processes and materials for forming the hard mask layer 194 and the metal layer 200 may be the same as, or similar to, those used to form the hard mask layer 194 and the metal layer 200 in the previous embodiments. For the purpose of brevity, the descriptions of these processes are not repeated herein.

By forming an air spacer 192 at the sidewalls of the power via structure 175 to provide power from the back side, the metal routing flexibility may be improved, and the parasitic capacitance between the gate structure 168 and the power via structure 175 may be reduced. The power via structure 175 may be formed by forming a dummy power via structure 175 first, and the dummy power via structure 175 is replaced after the substrate 102 has been flipped.

As described previously, an air spacer 192 may be formed between the gate structure 150 and the power via structure 175. The power via structure 175 may increase metal routing flexibility, and the air spacer 192 may reduce the parasitic capacitance, and the device performance may be enhanced. In some embodiments as shown in FIG. 2A, the air spacer 192 is enlarged by increasing the deposition rate of the sealing layer 190. In some embodiments as shown in FIG. 3A, a glue layer 202 is formed at the sidewalls of the power via structure 175. In some embodiments as shown in FIG. 4K, the power via structure 175 is formed from the back side. In some embodiments as shown in FIG. 5A, the power via structure 175 is formed by forming a dummy power via structure 177 first and replacing the dummy power via structure 177 from the back side.

Embodiments of a semiconductor device structure and a method for forming the same are provided. By forming air spacers between the power via structure and the gate structure, the parasitic capacitance may be reduced while the metal routing flexibility increased. The device performance may be enhanced.

In some embodiments, a method for forming a semiconductor device structure is provided. The method for forming a semiconductor device structure includes forming nanostructures over a substrate. The method for forming a semiconductor device structure also includes forming a gate structure surrounding the nanostructures. The method for forming a semiconductor device structure also includes forming source/drain structures over opposite sides of the gate structure. The method for forming a semiconductor device structure also includes forming a trench beside the source/drain structures. The method for forming a semiconductor device structure also includes depositing a first liner layer in the trench. The method for forming a semiconductor device structure also includes depositing a dummy material layer over the first liner layer. The method for forming a semiconductor device structure also includes etching the dummy material layer. The method for forming a semiconductor device structure also includes depositing a second liner layer over the dummy material layer. The method for forming a semiconductor device structure also includes forming a power via structure in the trench. The method for forming a semiconductor device structure also includes removing the dummy material layer to form an opening between the first liner layer and the second liner layer. The method for forming a semiconductor device structure also includes forming a sealing layer over the opening. An air spacer is formed under the sealing layer.

In some embodiments, a method for forming a semiconductor device structure is provided. The method for forming a semiconductor device structure includes forming a fin structure over a substrate. The method for forming a semiconductor device structure also includes forming a gate structure over the fin structure. The method for forming a semiconductor device structure also includes forming source/drain structures beside the gate structure. The method for forming a semiconductor device structure also includes forming a dielectric layer over the source/drain structures. The method for forming a semiconductor device structure also includes patterning the dielectric layer to expose the substrate between the source/drain structures. The method for forming a semiconductor device structure also includes depositing a first liner layer over the substrate. The method for forming a semiconductor device structure also includes depositing a dummy material layer over the first liner layer. The method for forming a semiconductor device structure also includes removing the top portion of the dummy material layer. The method for forming a semiconductor device structure also includes depositing a second liner layer over the dummy material layer and the first liner layer. The method for forming a semiconductor device structure also includes depositing a power via material. The method for forming a semiconductor device structure also includes planarizing the power via material to expose the top surface of the dielectric layer. The method for forming a semiconductor device structure also includes forming a contact structure over the power via material. The method for forming a semiconductor device structure also includes flipping the substrate. The method for forming a semiconductor device structure also includes removing the dummy material layer to form an opening. The method for forming a semiconductor device structure also includes sealing the opening to form an air spacer. The method for forming a semiconductor device structure also includes forming a metal layer under the power via material.

In some embodiments, a semiconductor device structure is provided. The semiconductor device structure includes nanostructures formed over a substrate. The semiconductor device structure also includes nanostructures formed over a substrate. The semiconductor device structure also includes a gate structure surrounding the nanostructures. The semiconductor device structure also includes source/drain structures formed over opposite sides of the gate structure. The semiconductor device structure also includes a power via structure formed beside the source/drain structures. The semiconductor device structure also includes a contact structure formed over the power via structure. The semiconductor device structure also includes a metal layer formed under the power via structure. An air spacer is formed between the power via structure and the source/drain structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming nanostructures over a substrate;
forming a gate structure surrounding the nanostructures;
forming source/drain structures over opposite sides of the gate structure;
forming a trench beside the source/drain structures;
depositing a first liner layer in the trench;
depositing a dummy material layer over the first liner layer;
etching the dummy material layer;
depositing a second liner layer over the dummy material layer;
forming a power via structure in the trench;
removing the dummy material layer to form an opening between the first liner layer and the second liner layer; and
forming a sealing layer over the opening and an air spacer under the sealing layer.

2. The method for forming the semiconductor device structure as claimed in claim 1, further comprising:
forming a contact structure at a front side of the power via structure; and
forming a metal layer at a back side of the power via structure.

3. The method for forming the semiconductor device structure as claimed in claim 1, wherein the sealing layer is formed over sidewalls of the first liner layer and the second liner layer.

4. The method for forming the semiconductor device structure as claimed in claim 1, further comprising:
forming a glue layer over the second liner layer.

5. The method for forming the semiconductor device structure as claimed in claim 1, further comprising:
flipping the substrate,
wherein the power via structure is formed after flipping the substrate.

6. The method for forming the semiconductor device structure as claimed in claim 1, further comprising:
forming a dummy power via structure in the trench;
flipping the substrate; and
removing the dummy power via structure.

7. The method for forming the semiconductor device structure as claimed in claim 1, wherein the first liner layer and the second liner layer are exposed in the air spacer.

8. The method for forming the semiconductor device structure as claimed in claim 1, wherein the first liner layer is in contact with the second liner layer.

9. A method for forming a semiconductor device structure, comprising:
forming a fin structure over a substrate;
forming a gate structure over the fin structure;
forming source/drain structures beside the gate structure;
forming a dielectric layer over the source/drain structures;
patterning the dielectric layer to expose the substrate between the source/drain structures;
depositing a first liner layer over the substrate;
depositing a dummy material layer over the first liner layer;
removing a top portion of the dummy material layer;
depositing a second liner layer over the dummy material layer and the first liner layer;
depositing a power via material;
planarizing the power via material to expose a top surface of the dielectric layer;
forming a contact structure over the power via material;
flipping the substrate;
removing the dummy material layer to form an opening;
sealing the opening to form an air spacer; and
forming a metal layer under the power via material.

10. The method for forming the semiconductor device structure as claimed in claim 9, further comprising:
patterning the gate structure to form trenches through the gate structure; and
filling an isolation material into the trenches.

11. The method for forming the semiconductor device structure as claimed in claim 10, wherein the first liner layer is deposited over the isolation material.

12. The method for forming the semiconductor device structure as claimed in claim 9, further comprising:
thinning the substrate to expose the power via material after flipping the substrate.

13. The method for forming the semiconductor device structure as claimed in claim 9, wherein a first end of the first liner layer is in direct contact with a first end of the second liner layer, and a second end of the first liner layer is separated from a second end of the second liner layer.

14. A semiconductor device structure, comprising:
nanostructures formed over a substrate;
a gate structure surrounding the nanostructures;
source/drain epitaxial structures formed over opposite sides of the gate structure;
a power via structure formed beside the source/drain structures;
a contact structure formed over the power via structure; and
a metal layer formed under the power via structure,
wherein an air spacer is formed between the power via structure and the source/drain epitaxial structures.

15. The semiconductor device structure as claimed in claim 14, further comprising:
a first liner layer formed over sidewalls of the source/drain epitaxial structures;
a second liner layer formed over sidewalls of the power via structure,
wherein the air spacer is formed between the first liner layer and the second liner layer.

16. The semiconductor device structure as claimed in claim 15, further comprising:
a sealing layer formed between the first liner layer and the second liner layer near the metal layer.

17. The semiconductor device structure as claimed in claim 16, wherein the air spacer is surrounded by the sealing layer.

18. The semiconductor device structure as claimed in claim 14, further comprising:
a glue layer formed over sidewalls of the power via structure.

19. The semiconductor device structure as claimed in claim 14, wherein the power via structure partially overlaps the contact structure.

20. The semiconductor device structure as claimed in claim 14, wherein a top surface of the power via structure near the contact structure is wider than a bottom surface of the power via structure near the metal layer.
